(19) United States
(12) Patent Application Publication
(10) Pub. No.: US 2009/0123642 A1
(43) Pub. Date: May 14, 2009

(54) EPOXY RESIN COMPOSITION, CONDUCTIVE FILM FORMING METHOD, CONDUCTIVE PATTERN FORMING METHOD, AND MULTILAYERED WIRING BOARD MANUFACTURING METHOD

(75) Inventor: Hiroshi Sato, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM Corporation, Tokyo (JP)

(21) Appl. No.: 12/092,531

(22) PCT Filed: Nov. 6, 2006
(86) PCT No.: PCT/JP2006/322508

§ 371 Date: May 2, 2008

(30) Foreign Application Priority Data
Nov. 4, 2005 (JP) 2005-320962
Feb. 28, 2006 (JP) 2006-053430

(51) Int. Cl. H05K 3/10; C08F 2/46; H05K 3/00

(52) U.S. Cl. 427/98.5; 522/170; 427/99.1

(57) ABSTRACT

The present invention discloses a thermosetting epoxy resin composition containing an epoxy resin having two or more epoxy groups in one molecule, a hardener having two or more functional groups that reacts with the epoxy groups in one molecule, and a photopolymerization initiator, and a method of forming a conductive film, a method of forming a conductive pattern, and a method of manufacturing a multilayered wiring board using the epoxy resin composition.

### TECHNICAL FIELD

The invention relates to an epoxy resin composition, a method of forming a conductive film, a conductive pattern forming method and a multilayered wiring board manufacturing method, more particularly to an epoxy resin composition containing an epoxy resin suitable for producing a graft polymer, a conductive film using the epoxy resin as a substrate, an epoxy resin composition suitable for a conductive pattern and a multilayered wiring board, and a method of forming a conductive film, a conductive pattern forming method, and a multilayered wiring board manufacturing method using the epoxy resin composition.

### BACKGROUND ART

A wiring board having a circuit on the surface of an insulating substrate is widely used for electronic parts and semiconductor elements. With recent demands for miniaturized and highly functional electronics, high-density and thinned circuits are desired with respect to the wiring board.

As a method of manufacturing a multilayered wiring board, conventionally, there is a so-called sequential laminating method in which copper foils are disposed on an inner layer circuit board with a prepreg interposed therebetween and molded into one by heat with a hot plate press, the prepreg being generated by impregnating a substrate such as a glass fabric with, for example, an insulating resin. However, in the sequential laminating method, it is difficult to obtain a desired thinned circuit board since interposing the prepreg is essential, and thus, it is difficult to respond to the demands for high-density and thinned multilayered wiring boards under the current situation.

Contrarily, a method of manufacturing a multilayered wiring board by a so-called build-up method, which allows direct formation of a conductor circuit on an insulating resin layer without hot pressure molding using a hot plate press, has received attentions in recent years. According to the method of manufacturing a multilayered wiring board by the build-up method, interposed materials for adhesion between layers are unnecessary since a conductor circuit layer and an insulating resin layer are alternately formed, laminated, and multilayered, whereby it is possible to respond to the demands for high-density and thinned circuit boards.

However, the multilayered wiring board manufactured by the build-up method has lower adhesion between the insulating resin layer and the conductor circuit than the multilayered wiring board manufactured by hot pressure molding with the prepreg, so that reduced peeling strength tends to be obtained. In particular, mass production by the build-up method results in much lower peeling strength, which is caused by an uneven surface shape due to surface roughening of the insulating resin layer, than mass production by the sequential laminating method. The reduction of the peeling strength arises problems in that it greatly affects connection reliability of the circuit or interlayer insulation.

To address these problems, a technique in which short wave ultraviolet rays are irradiated before or after roughening of the insulating resin layer has been suggested. (e.g., see Japanese Patent Application Laid-Open (JP-A) No. 2001-85840). With this technique, it is possible to improve a peeling strength by increased roughening process solution wettability or adsorption property of an electroless plating catalyst after roughening. Nevertheless, it is impossible to obtain a sufficient adhesion strength for forming a fine circuit having uniformity and high reliability in practice, so that it is a fact that connection reliability and satisfactory conductivity cannot be obtained. In addition, complicated steps such as resist application, resist exposure, etching, and resist removal are required, and measures to process etching waste water are necessary in the technique.

There is a need for an epoxy resin composition containing an epoxy resin suitable for producing a graft polymer, which has an excellent peeling strength and conductivity, and a conductive film forming method, a conductive pattern forming method and a multilayered wiring board manufacturing method using the epoxy resin composition.

### DISCLOSURE OF INVENTION

The invention has been made in view of the above circumstances and a first aspect of the invention provides a thermosetting epoxy resin composition containing: an epoxy resin having two or more epoxy groups in one molecule; a hardener having two or more functional groups that react with the epoxy groups in one molecule; and a photopolymerization initiator.

A second aspect of the invention provides a conductive film forming method including: (a) forming an epoxy resin layer including the thermosetting epoxy resin composition of the first aspect on an insulating substrate; (b) forming a graft polymer on a surface of the epoxy resin layer by applying energy to the entire surface of the epoxy resin layer and bonding a polymer having a functional group that interacts with an electroless plating catalyst or a precursor thereof to the entire surface; (c) providing the electroless plating catalyst or the precursor thereof to the graft polymer; and (d) forming a conductive film by performing electroless plating.

A third aspect of the invention provides a conductive pattern forming method including: (A) forming an epoxy resin layer including the thermosetting epoxy resin composition of the first aspect on an insulating substrate; (B) forming a graft polymer on a surface of the epoxy resin layer by pattern-wise applying energy to the surface of the epoxy resin layer and bonding a polymer having a functional group that interacts with an electroless plating catalyst or a precursor thereof to a portion of the epoxy resin layer to which portion energy has been applied; (C) providing the electroless plating catalyst or the precursor thereof to the graft polymer; and (D) forming a conductive pattern by performing electroless plating.

A fourth aspect of the invention provides a multilayered wiring board manufacturing method including: (a′) forming an epoxy resin layer including the thermosetting epoxy resin composition of the first aspect on a first conductive pattern that is formed on an insulating substrate; (b′) forming a graft polymer pattern on the epoxy resin layer by applying a compound having a double bond and a compound having a functional group that interacts with an electroless plating catalyst or a precursor thereof and pattern-wise irradiating the surface of the epoxy resin layer with ultraviolet light; (c′) forming a via hole in the epoxy resin layer before or after the graft polymer pattern is formed on the epoxy resin layer; and (d′) forming a conductive path by subjecting the epoxy resin layer to electroless plating so as to form a second conductive pattern corresponding to the graft polymer pattern and a buried via that electrically connects the first conductive pattern with the second conductive pattern.

The multilayered wiring board manufacturing method of the invention has two embodiments: a first embodiment of (a′) forming an epoxy resin layer including the thermosetting epoxy resin composition of the first aspect on a first conductive pattern that is formed on an insulating substrate; (c′) forming a via hole in the epoxy resin layer; (b′) forming a graft polymer pattern on the epoxy resin layer by applying a compound having a double bond and a compound having a functional group that interacts with an electroless plating catalyst or a precursor thereof and pattern-wise irradiating the surface of the epoxy resin layer with ultraviolet light; and (d′) forming a conductive path by subjecting the epoxy resin layer to electroless plating so as to form a second conductive pattern corresponding to the graft polymer pattern and a buried via that electrically connects the first conductive pattern with the second conductive pattern, and a second embodiment of (a′) forming an epoxy resin layer including the thermosetting epoxy resin composition of the first aspect on a first conductive pattern that is formed on an insulating substrate; (b′) forming a graft polymer pattern on the epoxy resin layer by applying a compound having a double bond and a compound having a functional group that interacts with an electroless plating catalyst or a precursor thereof and pattern-wise irradiating the surface of the epoxy resin layer with ultraviolet light; (c′) forming a via hole in the epoxy resin layer; and (d′) forming a conductive path by subjecting the epoxy resin layer to electroless plating so as to form a second conductive pattern corresponding to the graft polymer pattern and a buried via that electrically connects the first conductive pattern with the second conductive pattern.

### BEST MODE FOR CARRYING OUT THE INVENTION

In the conductive film forming method, the conductive pattern forming method, and the multilayered wiring board manufacturing method of the invention, a graft polymer pattern is formed on the surface of an epoxy resin layer including the thermosetting epoxy resin composition of the invention, which contains at least one epoxy resin each having two or more epoxy groups in one molecule, at least one hardener each having two or more functional groups that react with the epoxy groups in one molecule, and at least one photopolymerization initiator, and electroless plating is carried out using the graft polymer as a starting point.

Since the graft polymer is firmly bonded to the surface of the epoxy resin layer via covalent bond, a plated film (metal film) formed using the graft polymer as a starting point is also firmly bonded to the epoxy resin of the epoxy resin layer. Thereby, strong adhesion between the epoxy resin layer and the plated film is achieved without surface roughening of an insulating layer, which is conventionally conducted, and excellent peeling strength, conductivity and connection reliability can be obtained. In addition, since the surface is not roughened and flat, the conductive film formed by the conductive film forming method, the conductive pattern obtained by the conductive pattern forming method, and the multilayered wiring board obtained by the multilayered wiring board manufacturing method have preferred properties for high-frequency power transmission.

According to the methods of the invention, it is possible to form fine wiring that has strong adhesion with respect to an epoxy resin and that is useful for conductive films, conductive patterns, and multilayered wiring boards.

In the invention, the epoxy resin composition preferably includes at least 20 mass % of an epoxy resin relative to all the components of the epoxy resin composition. The content of the epoxy resin in all the components of the epoxy resin composition is preferably 80 mass % or less.

Namely, to improve characteristics of the epoxy resin such as mechanical strength, heat resistance, weather resistance, flame resistance, water resistance, and electrical characteristics in forming an epoxy resin layer including the epoxy resin composition, the epoxy resin composition preferably contains 20 mass % or more of an epoxy resin relative to all the components of the epoxy resin composition. The epoxy resin composition contains at least one photopolymerization initiator in view of the adhesion strength and the conductivity of a conductor, and may further contain any other resin and at least one filler to control the conductivity of the composition.

When the epoxy resin composition contains at least one resin other than the epoxy resin, the content of other resin(s) is generally 30 to 300 mass %, and preferably 50 to 200 mass % with respect to the epoxy resin. When the content of other resin(s) relative to the epoxy resin is less than 30 mass %, the effects of inclusion of other resin(s) cannot be sufficiently obtained. When the content of other resin(s) relative to the epoxy resin exceeds 300 mass %, characteristics of the epoxy resin such as strength may deteriorate, and reaction for forming a graft polymer does not easily proceed.

The epoxy resin composition of the invention includes (A) at least one epoxy compound having two or more epoxy groups in one molecule, (B) at least one compound having two functional groups that react with the two or more epoxy groups in one molecule (Hereinafter, refereed to as a hardener), and (C) at least one photopolymerization initiator, as described above.

Each of the functional groups in the compound (B) is selected from a carboxyl group, a hydroxyl group, an amino group and a thiol group.

(A) The epoxy compound (including compounds called epoxy resins) has two or more epoxy groups, preferably has 2 to 50 epoxy groups, and more preferably has 2 to 20 epoxy groups in one molecule. The epoxy group has an oxirane ring structure, and examples of such an epoxy group include a glycidyl group, an oxyethylene group, and an epoxycyclohexyl group. Such polyvalent epoxy compounds are disclosed in, for example, EPOXY RESIN HANDBOOK edited by Shinbo Masaki and published by Nikkan Kogyo Shimbun, Ltd. in 1987, and compounds disclosed therein can be used in the invention.

Specific examples of the epoxy compound include bisphenol A-type epoxy resin, bisphenol F-type epoxy resin, brominated bisphenol A-type epoxy resin, bisphenol S-type epoxy resin, diphenyl ether-type epoxy resin, hydroquinone-type epoxy resin, naphthalene-type epoxy resin, biphenyl-type epoxy resin, fluorene-type epoxy resin, phenol novolac-type epoxy resin, orthocresolnovolac-type epoxy resin, toris-hydroxyphenylmethane-type epoxy resin, trifunctional-type epoxy resin, tetraphenyloletane-type epoxy resin, dicyclopentadienephenol-type epoxy resin, hydrogenated bisphenol A-type epoxy resin, bisphenol A-containing nuclear polyol-type epoxy resin, polypropylene glycol-type epoxy resin, glycidylester-type epoxy resin, glycidylamine-type epoxy resin, glyoxal-type epoxy resin, alicyclic epoxy resin, and heterocyclic epoxy resin. One of these epoxy resins may be used alone, and two or more of them may be used together. Epoxy resins having excellent heat resistance can be obtained by using polyfunctional epoxy, epoxy having a low epoxy equivalent amount, naphthalene-type epoxy, or a dicyclopentadiene-type epoxy.

Examples of the hardener (B) include polyfunctional carboxylic acid compounds such as terephthalic acid, bifunctional phenol compounds such as bisphenol-A, bisphenol-F, bisphenol-S, resorcinol derivatives, and catechol derivatives, phenol resins such as phenol/novolac resin and cresol/novolac resin, and polyfunctional amino compounds such as amino resin, 1,3,5-triaminotriazine, and 4,4′-diaminodiphenylsulfone. Among these, the hardener is preferably a compound having at least two of hydroxyl and amino groups as the functional groups that react with the epoxy groups.

As for the amount of the hardener(s) in the epoxy resin composition, the ratio of the number of the functional groups of the hardener(s) to that of the epoxy groups of the epoxy resin(s) is preferably in the range of 0.1 to 5.0, and more preferably in the range of 0.3 to 2.0.

The photopolymerization initiator (C) preferably has at least one photopolymerizable group that can radically, anionically or cationically polymerizes and that has as at least one pendant at least one site having a photopolymerization initiation ability. In other words, the photopolymerization initiator has a structure in which at least one photopolymerizable group and at least one functional group having a polymerization initiation ability coexist in one molecule.

Examples of the site having a photopolymerization initiation ability include those derived from (a) aromatic ketones, (b) onium salt compounds, (c) organic peroxides, (d) thio compounds, (e) hexaarylbiimidazole compounds, (f) ketoxime ester compounds, (g) borate compounds, (h) azinium compounds, (i) active ester compounds, (j) carbon-halogen bond-containing compounds, and (k) pyridium compounds. Hereinafter, specific examples of the compounds (a) to (k) will be described, but the invention is not limited by such examples.

### (a) Aromatic Ketones

The aromatic ketone (a) preferred in the invention as the compound from which the site having a photopolymerization initiation ability is derived can be a compound having a benzophenone or thioxanthone skeleton and described in “RADIATION CURING IN POLYMER SCIENCE AND TECHNOLOGY” J. P. Fouassier, J. F. Rabek (1993), p. 77-117. Examples of such compounds include the following compounds.

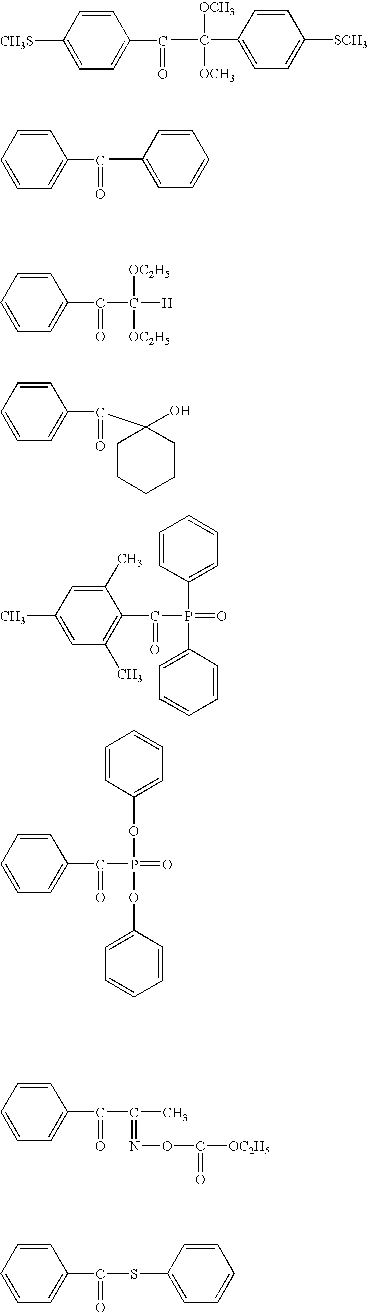

The aromatic ketone (a) is preferably α-thiobenzophenone compound described in Japanese Patent Application Publication (JP-B) No. S47-6416, or a benzoin ether compound described in JP-B No. 47-3981, such as a compound shown below.

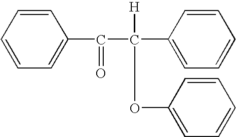

Also, the aromatic ketone (a) is preferably an α-substituted benzoin compound described in JP-B No. S47-22326, such as a compound shown below.

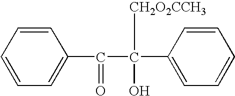

Furthermore, the aromatic ketone (a) is preferably a benzoin derivative described in JP-B No. S47-23664, an aroylphosphonic acid ester described in JP-A No. S57-30704, or dialkoxybenzophenone described in JP-B No. S60-26483, such as a compound shown below.

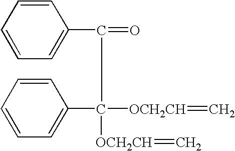

In addition, the aromatic ketone (a) is preferably benzoin ether described in JP-B No. S60-26403 or JP-A No. S62-81345, such as a compound shown below.

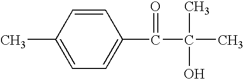

Moreover, the aromatic ketone (a) is preferably α-aminobenzophenone described in JP-B No. H01-34242, U.S. Pat. No. 4,318,791, or EP No. 0284561A1, such as a compound shown below.

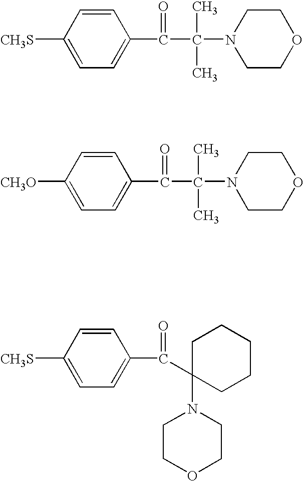

Also, the aromatic ketone (a) is preferably p-di(dimethylaminobenzoyl)benzene described in JP-A No. H02-211452, such as a compound shown below.

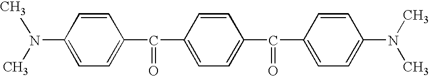

Furthermore, the aromatic ketone (a) is preferably thio-substituted aromatic ketone described in JP-A No. S61-194062, such as a compound shown below.

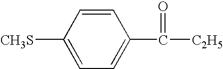

In addition, the aromatic ketone (a) is preferably acylphosphine sulfide described in JP-B No. H02-9597, such as a compound shown below.

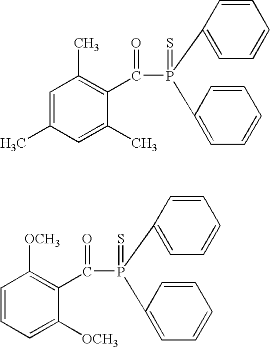

Further, the aromatic ketone (a) is preferably acylphosphine described in JP-B No. H02-9596, such as a compound shown below.

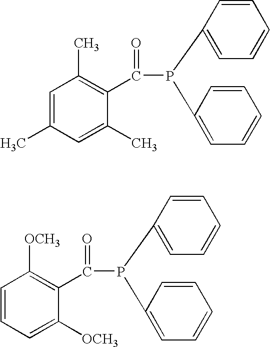

Moreover, the aromatic ketone (a) is preferably thioxanthone described in JP-B No. S63-61950; or coumarin described in JP-B No. S59-42864.

### (b) Onium Salt Compound

The onium salt compound (b) preferred in the invention as the compound from which the site having a photopolymerization initiation ability is derived can be any of compounds represented by the following Formulas (1) to (3).

Ar¹—I—Ar²(Z²)⁻ Formula (1)

Ar³—N⁺≡N(Z³)⁻ Formula (2)

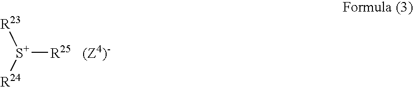

In Formula (1), Ar¹ and Ar² independently represent a substituted or unsubstituted aryl group having 20 or less carbon atoms. Typical examples of the substituent(s) of the substituted aryl group include halogen atoms, a nitro group, alkyl groups having 12 or less carbon atoms, alkoxy groups having 12 or less carbon atoms, and aryloxy groups having 12 or less carbon atoms. (Z²)⁻ represents a counter ion selected from the group consisting of halogen ions, a perchlorate ion, a carboxylate ion, a tetrafluoroborate ion, a hexafluorophosphate ion, and sulfonate ions, and is preferably a perchlorate ion, a hexafluorophosphate ion, or an arylsulfonate ion.

In Formula (2), Ar³ represents a substituted or unsubstituted aryl group having 20 or less carbon atoms. Typical examples of the substituent(s) of the substituted aryl group include halogen atoms, a nitro group, alkyl groups having 12 or less carbon atoms, alkoxy groups having 12 or less carbon atoms, aryloxy groups having 12 or less carbon atoms, alkylamino groups having 12 or less carbon atoms, dialkylamino groups having 12 or less carbon atoms, arylamino groups having 12 or less carbon atoms, and diarylamino groups having 12 or less carbon atoms. (Z³)⁻ represents a counter ion having the same meaning as (Z²)⁻.

In Formula (3), R²³, R²⁴ and R²⁵ may be the same as or different from each other, and independently represent a substituted or unsubstituted hydrocarbon group having 20 or less carbon atoms. Typical examples of the substituent(s) of the substituted hydrocarbon group include halogen atoms, a nitro group, alkyl groups having 12 or less carbon atoms, alkoxy groups having 12 or less carbon atoms, and aryloxy groups having 12 or less carbon atoms. (Z⁴)⁻ represents a counter ion having the same meaning as (Z²)⁻.

Preferred examples of the onium salt compound (b) include compounds described in paragraph Nos. [0030] to [0033] of JP-A No. 2001-133969, paragraph Nos. [0048] to [0052] of JP-A No. 2001-305734, and paragraph Nos. [0015] to [0046] of JP-A No. 2001-343742.

### (c) Organic Peroxide

Examples of the organic peroxide (c) preferred in the invention as the compound from which the site having a photopolymerization initiation ability is derived include almost all organic compounds having one or more oxygen-oxygen bonds in the molecule. Specific examples thereof include methyl ethyl ketone peroxide, cyclohexanone peroxide, acetylacetone peroxide, 1,1,3,3-tetramethylbutyl hydroperoxide, di-t-butyl peroxide, t-butyl peroxylaurate, t-butyl peroxycarbonate, 3,3′4,4′-tetra-(t-butylperoxycarbonyl)benzophenone, 3,3′4,4′-tetra-(t-amylperoxycarbonyl)benzophenone, 3,3′4,4′-tetra-(t-hexylperoxycarbonyl)benzophenone, 3,3′4,4′-tetra-(t-octylperoxycarbonyl)benzophenone, 3,3′4,4′-tetra-(cumylperoxycarbonyl)benzophenone, 3,3′4,4′-tetra-(p-isopropylcumylperoxycarbonyl)benzophenone, carbonyl-di(t-butyl peroxy dihydrogen diphthalate), and carbonyl-di(t-hexylperoxy dihydrogen diphthalate).

### (d) Thio Compound

The thio compound (d) preferred in the invention as the compound from which the site having a photopolymerization initiation ability is derived may be a compound represented by the following Formula (4).

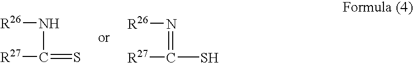

In Formula (4), R²⁶ represents an alkyl group, or a substituted or unsubstituted aryl group, and R²⁷ represents a hydrogen atom or an alkyl group. R²⁶ and R²⁷ may bond to each other to form a five- to seven-membered non-metal ring, which may include at least one hetero atom selected from oxygen, sulfur, and nitrogen atoms.

Specific examples of the thio compound represented by Formula (4) include compounds shown in the following Table 1.

TABLE 1

| No. | R²⁶ | R²⁷ |
|---|---|---|
| 1 | —H | —H |
| 2 | —H | —CH₃ |
| 3 | —C₆H₅ | —C₂H₅ |
| 4 | —C₆H₄—CH₃ | —C₄H₉ |
| 5 | —C₆H₄—OCH₃ | —CH₃ |

| | |
|---|---|
| 6 | —(CH₂)₂— |
| 7 | —CH(CH₃)—CH₂—S— |

### (e) Hexaarylbiimidazol Compound

The hexaarylbiimidazol compound (e) preferred in the invention as the compound from which the site having a photopolymerization initiation ability is derived may be any of lophin dimers disclosed in JP-B Nos. S45-37377 and S44-86516. Specific examples thereof include 2,2′-bis(o-chlorophenyl-4,4′,5,5′-tetraphenylbiimidazole, 2,2′-bis(o-bromophenyl)-4,4′,5,5′-tetraphenylbiimidazole, 2,2′-bis(o,p-dichlorophenyl)-4,4′,5,5′-tetraphenylbiimidazole, 2,2′-bis(o-chlorophenyl)-4,4′,5,5′-tetra(m-methoxyphenyl)biimidazole, 2,2′-bis(o,o′-dichlorophenyl)-4,4′,5,5′-tetraphenylbiimidazole, 2,2′-bis(o-nitrophenyl)-4,4′,5,5′-tetraphenylbiimidazole, 2,2′-bis(o-methylphenyl)-4,4′,5,5′-tetraphenylbiimidazole, and 2,2′-bis(o-trifluorophenyl)-4,4′,5,5′-tetraphenylbiimidazole.

### (f) Ketoxime Ester Compound

Examples of the ketoxime ester compound (f) preferred in the invention as the compound from which the site having a photopolymerization initiation ability is derived include 3-benzyoloxyiminobutan-2-one, 3-acetoxyiminobutan-2-one, 3-propionyloxyiminobutan-2-one, 2-acetoxyiminopentan-3-one, 2-acetoxyimino-1-phenylpropan-1-one, 2-benzyoloxyimino-1-phenyl propan-1-one, 3-p-toluenesulfonyloxyiminobutan-2-one, and 2-ethoxycarbonyloxyimino-1-phenylpropan-1-one.

### (g) Borate Compound

The borate compound (g) preferred in the invention as the compound from which the site having a photopolymerization initiation ability is derived is, for example, a compound represented by the following Formula (5).

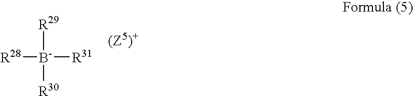

In Formula (5), R²⁸, R⁹, R³⁰, and R³¹ may be the same as or different from each other, and independently represent a substituted or unsubstituted alkyl group, a substituted or unsubstituted aryl group, a substituted or unsubstituted alkenyl group, a substituted or unsubstituted alkynyl group, or a substituted or unsubstituted heterocyclic group. At least two groups of R²⁸, R²⁹, R³⁰, and R³¹ may be bonded to each other to form a cyclic structure. At least one of the R²⁸, R²⁹, R³⁰, and R³¹ is a substituted or unsubstituted alkyl group. (Z⁵)⁺ represents an alkali metal cation or a quatenary ammonium cation.

In Formula (5), an alkyl group represented by R²⁸, R²⁹, R³⁰, and R³¹ may be linear, branched, or cyclic, and preferably has 1 to 18 carbon atoms. Specific examples of the unsubstituted alkyl group include methyl, ethyl, propyl, isopropyl, butyl, pentyl, hexyl, octyl, stearyl, cyclobutyl, cyclopentyl, and cyclohexyl groups. Examples of the substituted alkyl group include those obtained by replacing at least one hydrogen atom of the unsubstituted alkyl groups with at least one of halogen atoms (for example, —Cl, or —Br), a cyano group, a nitro group, aryl groups (preferably, a phenyl group), a hydroxy group, a —COOR³² group (Here, R³² represents a hydrogen atom, an alkyl group having 1 to 14 carbon atoms, or an aryl group), a —OCOR³³ group and a —OR³⁴ group (Here, R³³ and R³⁴ independently represent an alkyl group having 1 to 14 carbon atoms, or an aryl group), and the following substituent.

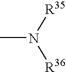

In the above substituent, R³⁵ and R³⁶ independently represent a hydrogen atom, an alkyl group having 1 to 14 carbon atoms, or an aryl group.

Specific examples of the compound represented by Formula (5) compound include compounds described in U.S. Pat. Nos. 3,567,453 and 4,343,891 and EP Nos. 109,772 and 109,773, and the following compounds.

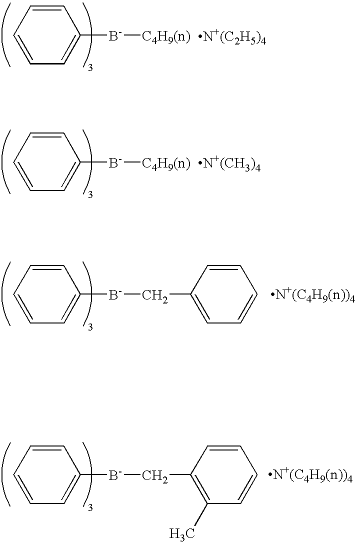

### (h) Azinium Salt Compound

Examples of the azinium salt compound (h) preferred in the invention as the compound from which the site having a photopolymerization initiation ability is derived include compounds having at least one N—O bond and described in JP-A Nos. S63-138345, S63-142345, S63-142346, and S63-143537 and JP-B No. S46-42363.

### (i) Active Ester Compound

Examples of the active ester compound (i) preferred in the invention as the compound from which the site having a photopolymerization initiation ability is derived include imidosulfonate compounds described in JP-B No. S62-6223, and active sulfonates described in JP-B No. S63-14340, and JP-A No. S59-174831.

### (j) Carbon-Halogen Bond-Containing Compound

The carbon-halogen bond-containing compound (j) preferred in the invention as the compound from which the site having a photopolymerization initiation ability is derived is, for example, a compound represented by the following Formula (6) or Formula (7).

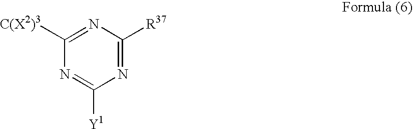

In Formula (6), X² represents a halogen atom, and Y² represents —C(X²)₃, —NH₂, —NHR³⁸, —NR³⁸, or —OR³⁸. R³⁸ represents a substituted or unsubstituted alkyl group, or a substituted or unsubstituted aryl group. R³⁷ represents —C(X²)₃, a substituted or unsubstituted alkyl group, a substituted or unsubstituted aryl group, or a substituted alkenyl group.

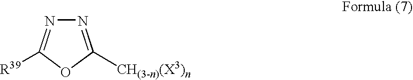

In Formula (7), R³⁹ represents a substituted or unsubstituted alkyl group, a substituted or unsubstituted alkenyl group, a substituted or unsubstituted aryl group, a halogen atom, a substituted or unsubstituted alkoxy group, a nitro group, or a cyano group. X³ represents a halogen atom. n is an integer of 1 to 3.

Specific examples of the compounds represented by Formulae (6) and (7) include the following compounds.

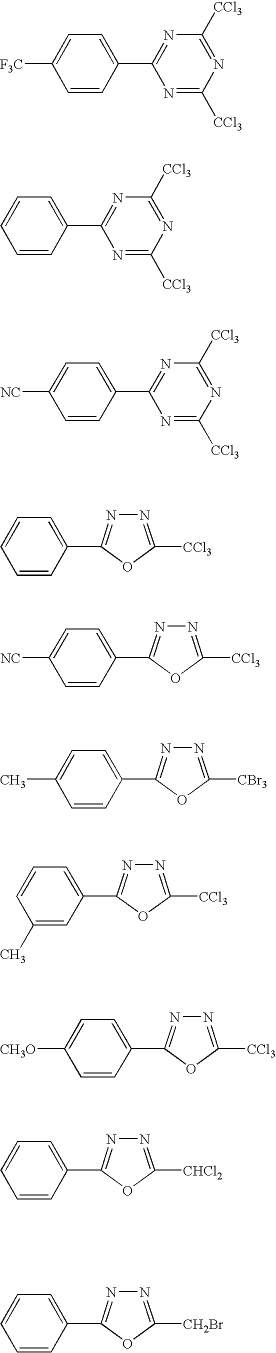

### (k) Pyridium Compound

The pyridium compound (k) preferred in the invention as the compound from which the site having a photopolymerization initiation ability is derived is, for example, a compound represented by the following Formula (8).

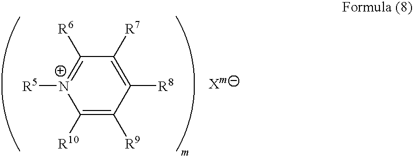

In Formula (8), R⁵ is preferably a hydrogen atom, a substituted or unsubstituted alkyl group, a substituted or unsubstituted aryl group, a substituted or unsubstituted alkenyl group, or a substituted or unsubstituted alkynyl group. R⁶, R⁷, R⁸, R⁹, and R¹⁰ may be the same as or different from each other and independently represent a hydrogen atom, a halogen atom or a monovalent organic residue. At least one of R⁶, R⁷, R⁸, R⁹, and R¹⁰ has a group represented by the following Formula (9). In addition, R⁵ and R⁶, R⁵ and R¹⁰, R⁶ and R⁷, R⁷ and R⁸, R⁸ and R⁹, and/or R⁹ and R¹⁰ may be bonded to each other to form a ring. Further, X represents a counter anion. m is an integer of 1 to 4.

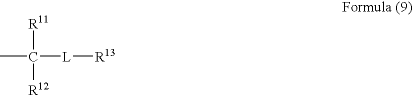

In Formula (9), R¹² and R¹³ independently represent a hydrogen atom, a halogen atom, a substituted or unsubstituted alkyl group, a substituted or unsubstituted aryl group, a substituted or unsubstituted alkenyl group, or a substituted or unsubstituted alkynyl group. R¹¹ represents a hydrogen atom, a substituted or unsubstituted alkyl group, a substituted or unsubstituted aryl group, a substituted or unsubstituted alkenyl group, a substituted or unsubstituted alkynyl group, a hydroxyl group, a substituted oxy group, a mercapto group, a substituted thio group, or a substituted or unsubstituted amino group. In addition, R¹² and R¹³, R¹¹ and R¹², and/or R¹¹ and R¹³ may be bonded to each other to form a ring. L represents a bivalent connecting group containing at least one hetero atom.

The compound from which the site having a photopolymerization initiation ability is derived is preferably a heat-resistant photopolymerization initiator, and, from this viewpoint, is preferably aromatic ketone.

The aromatic ketone preferably has a structure represented by the following Formula (I), (II), (III) or (IV).

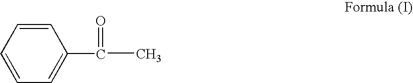

When a site having a photopolymerization initiation ability and derived from the structure represented by Formula (I) is bonded to a polymer chain to form a high molecular weight photopolymerization initiator, a connecting group bonding to the polymer chain is preferably bonded to the phenyl group of the site. Alternatively, the phenyl group may be directly bonded to the polymer chain.

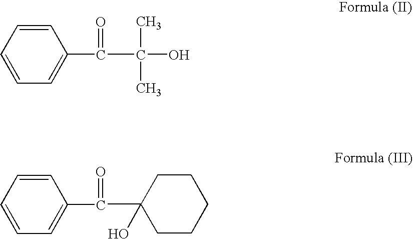

When a site having a photopolymerization initiation ability and derived from the structure represented by Formula (II) or (III) is bonded to a polymer chain to form a high molecular weight photopolymerization initiator, a connecting group bonding to the polymer chain is preferably bonded to the phenyl or hydroxyl group of the site. Alternatively, the phenyl or hydroxyl group may be directly bonded to the polymer chain.

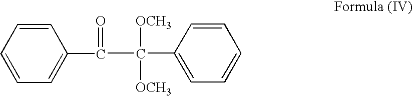

When a site having a photopolymerization initiation ability and derived from the structure represented by Formula (IV) is bonded to a polymer chain to form a high molecular weight photopolymerization initiator, a connecting group bonding to the polymer chain is preferably bonded to the phenyl group of the site. Alternatively, the phenyl group may be directly bonded to the polymer chain.

The connecting group is, for example, bivalent or trivalent. Specific examples of such a connecting group include —O—, —OCO—, —CO—, —OCONH—, —S—, —CONH—, —OCOO—, and —N═. The connecting group is preferably —O—, or —OCO—.

The photopolymerization initiator included in the epoxy resin composition of the invention may be a low or high molecular weight compound.

The low molecular weight photopolymerization initiator may be a known radical generating agent. Specific examples thereof include acetophenones, benzophenones, michler's ketone, benzoyl benzoate, benzoins, α-acyloxime ester, tetramethylthiuram monosulfide, trichloromethyltriazine and thioxanthone. In addition, a sulfonium salt, or an iodinium salt, which is usually used as an optical acid generating agent but, when irradiated with light, also serves as a radical generating agent, may be used in the invention.

To increase sensibility, the epoxy resin composition of the invention may further contain at least one sensitizer together with the optical radical polymerization initiator(s). Specific examples of the sensitizer include n-butylamine, triethylamine, tri-n-butylphosphine, and thioxanthone derivatives. The high molecular weight photopolymerization initiator may be a known optical radical generating agent. Such a high molecular weight optical radical generating agent may be a high molecular weight compound having at least one active carbonyl group on or in the side chains, which is disclosed in JP-A Nos. H09-77891 and H10-45927.

Examples of the high molecular weight photopolymerization initiator include the following compounds (a) to (n).

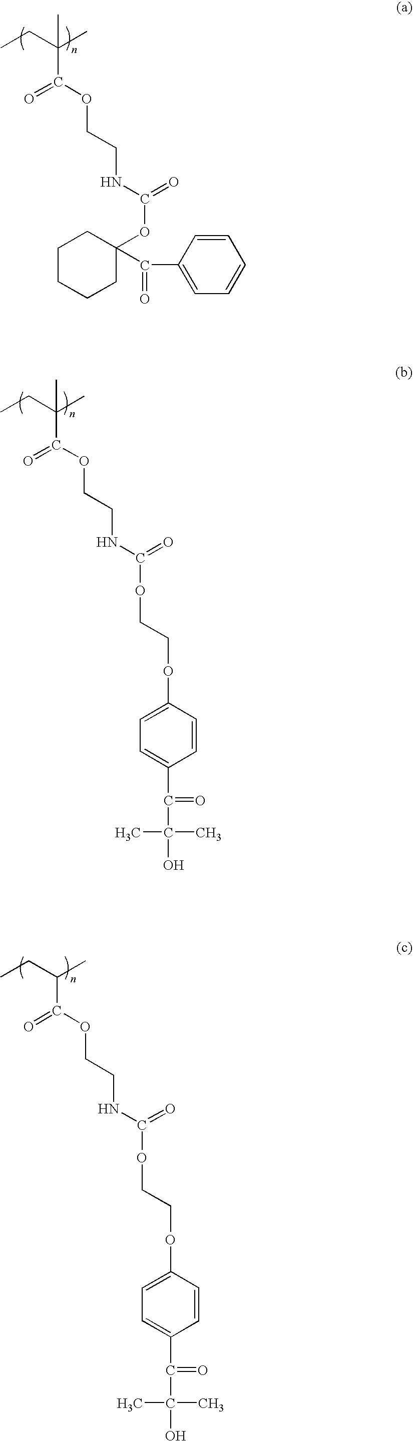

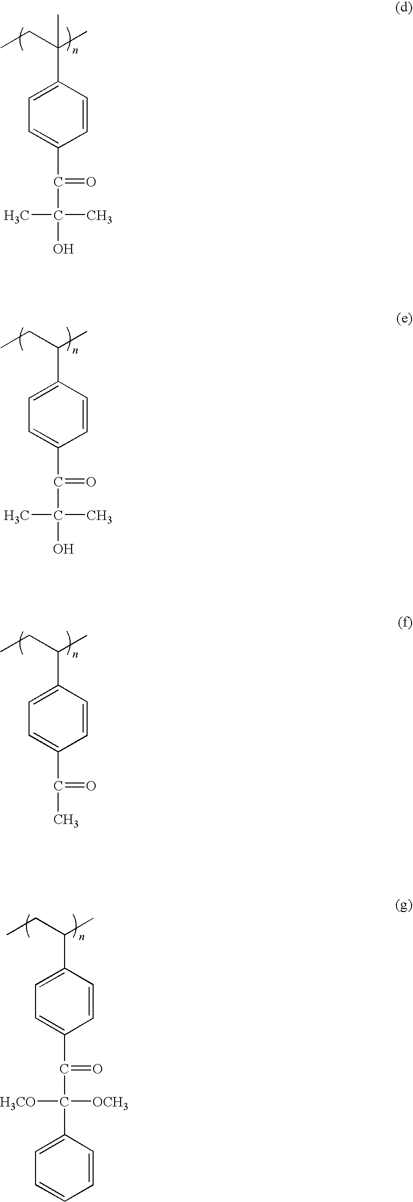

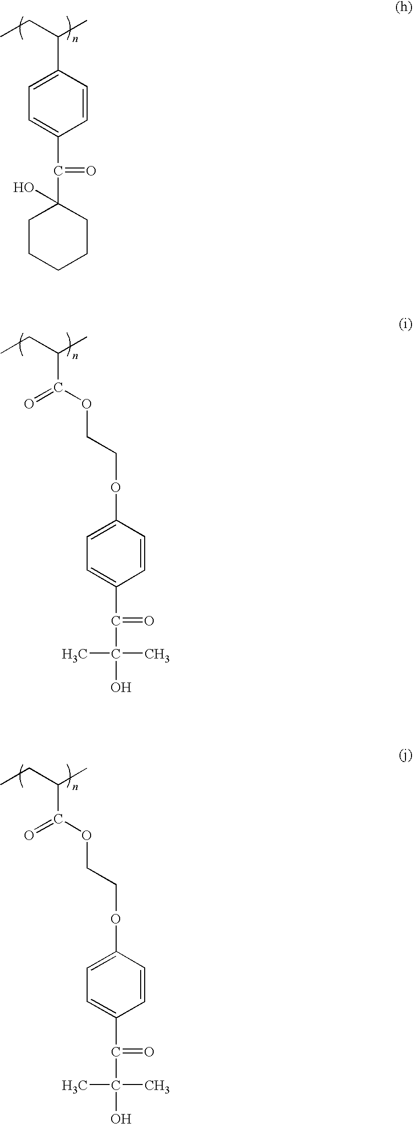

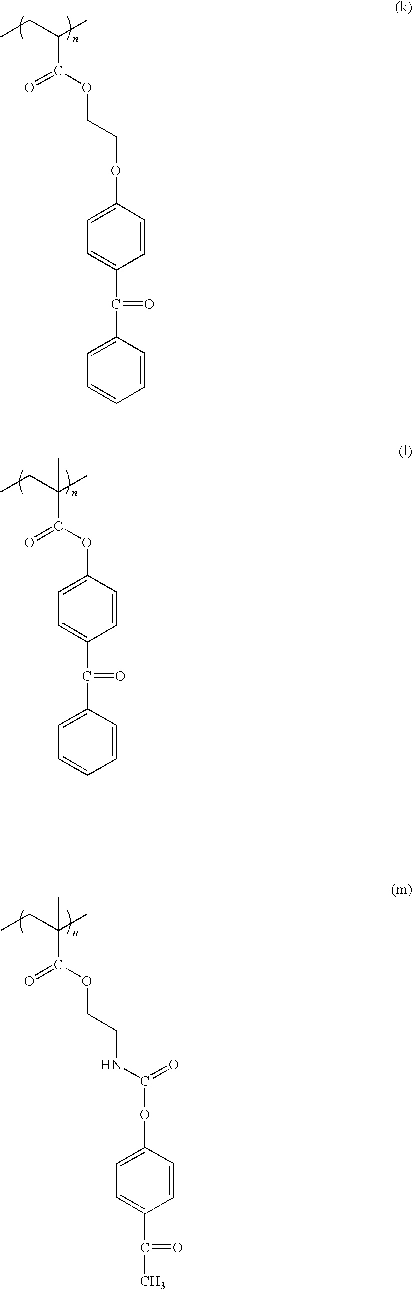

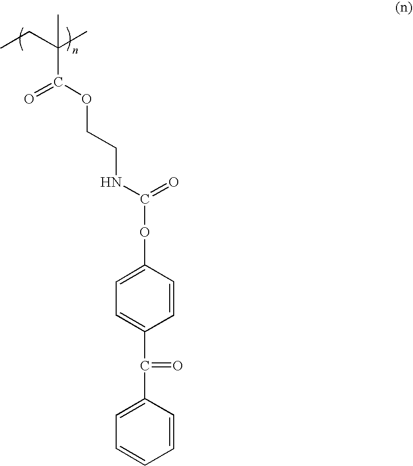

The photopolymerization initiator is preferably a high molecular weight photopolymerization initiator in view of graft polymerizing properties in graft formation of a conductive film forming method, a conductive pattern forming method, and a multilayered wiring board manufacturing method, which will be described in detail later.

The photopolymerization initiator may be a copolymer obtained by copolymerizing a monomer having a photopolymerization initiation group and other monomer and represented by the following Formula (O).

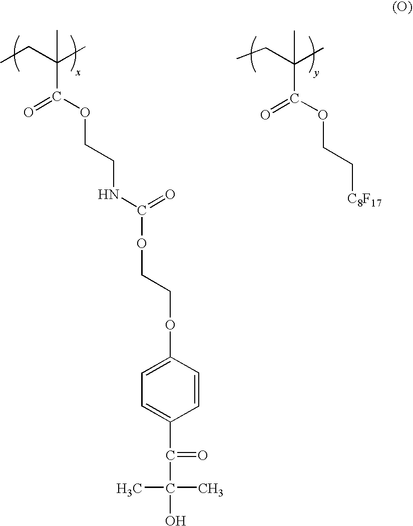

The (A) epoxy compound. (epoxy resin) included in the epoxy resin composition of the invention may have, in the molecule, a site having a photopolymerization initiation ability. When the (A) epoxy resin itself has a photopolymerization initiation ability and has the same function as that of the photopolymerization initiator, the epoxy resin composition may not contain a (C) photopolymerization initiator that is separate from the epoxy resin.

The epoxy resin having a photopolymerization initiation ability can be easily obtained by, for example, copolymerizing at least one monomer having an epoxy group with at least one monomer having a photopolymerization initiation group.

Specific examples of the copolymer obtained by copolymerizing a monomer having an epoxy group and a monomer having a photopolymerization initiation group and serving as the epoxy resin are shown below. However, the epoxy resin composition of the invention is not limited by these examples.

Each of x and y represents a mole fraction in the following formulas (C) to (N) showing copolymers. Here, the sum of x and y is 100, and none of x and y is 0.

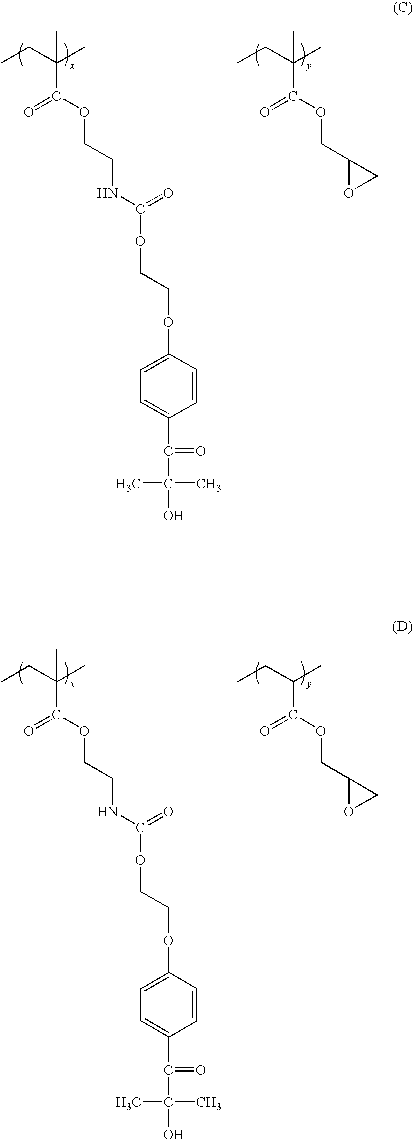

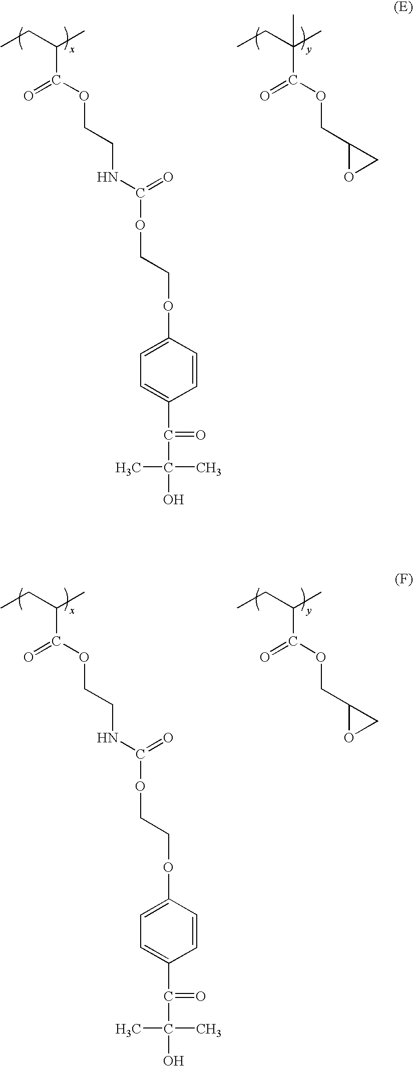

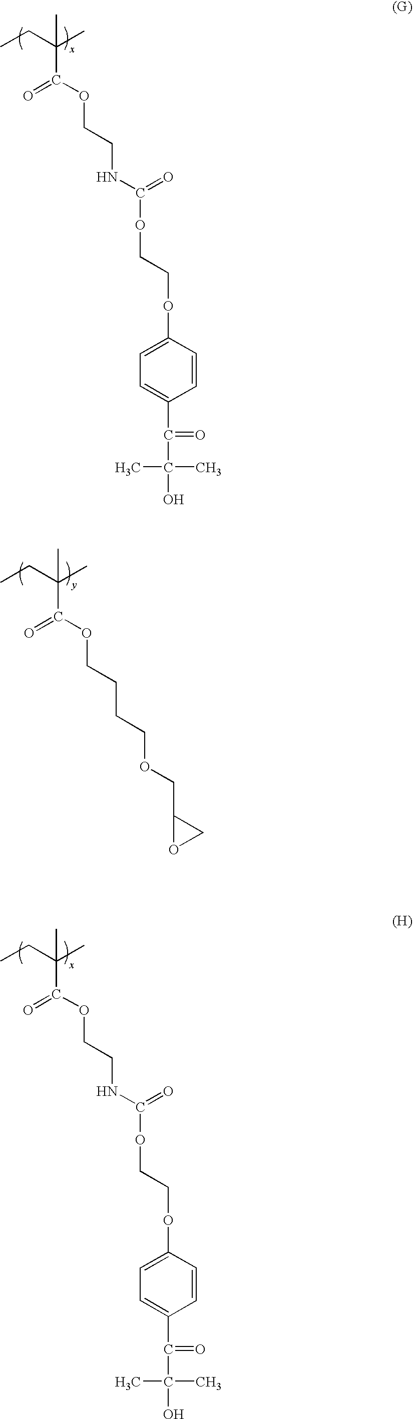

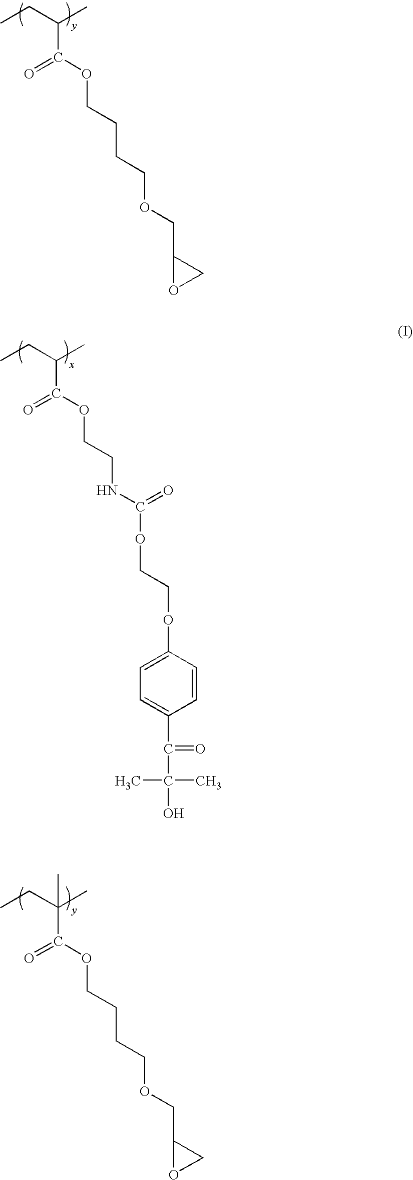

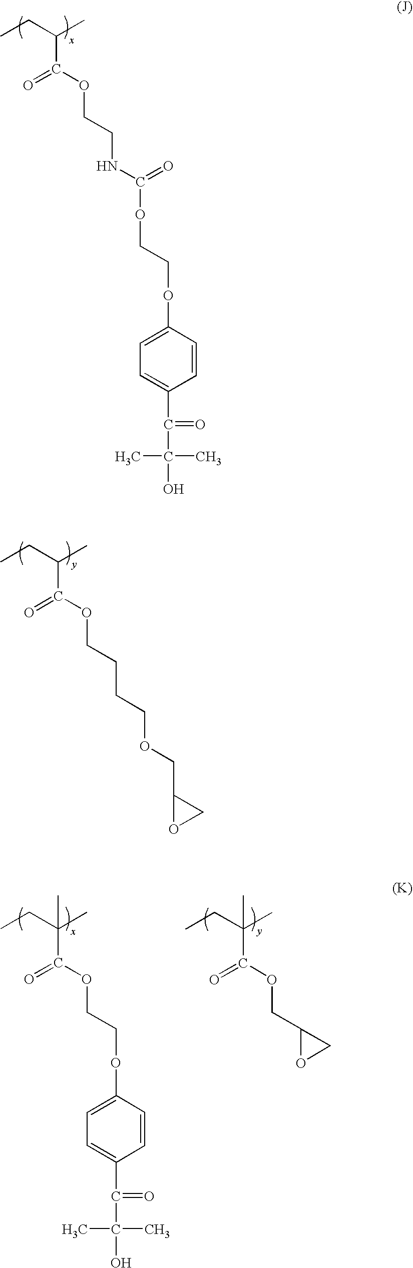

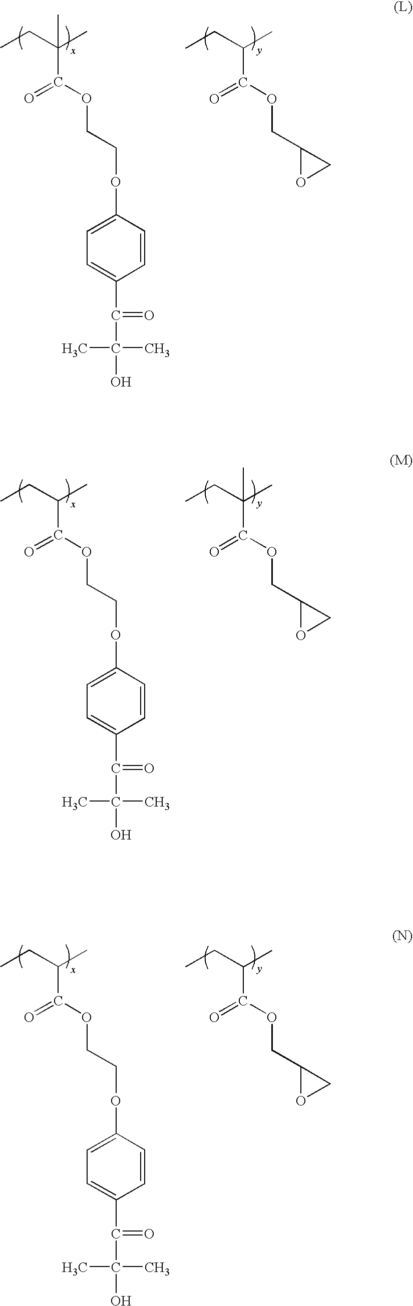

In these copolymers, x is preferably 5 to 70, and y is preferably 30 to 95 from the viewpoints of film strength and graft polymerizing properties. More preferably, x is 5 to 50, and y is 50 to 95. Even more preferably, x is 10 to 30, and y is 70 to 90.

A desired content of the photopolymerization initiator(s) contained in the epoxy resin composition used to form an epoxy resin layer in the conductive film forming method, the conductive pattern forming method, and the multilayered wiring board manufacturing method, which will be described in detail later, depends on the usage of a surface graft material used. The content of the photopolymerization initiator(s) is preferably in the range of 0.1 to 50 mass %, and more preferably in the range of 1.0 to 30.0 mass % with respect to the total solid matter of the epoxy resin composition.

If the content of the photopolymerization initiator(s) contained in the epoxy resin composition is less than 0.1 mass %, the epoxy resin composition has reduced graft polymerizing properties, adhesion strength and conductivity. If the content of the photopolymerization initiator is more than the 50 mass %, problems regarding thermal and electrical characteristics, such as a reduced glass-transition temperature Tg or an increased dielectric constant of an epoxy resin layer.

The epoxy resin composition has a radical generating ability. The epoxy resin layer obtained by using the epoxy resin composition having a radical generating ability has increased graft polymerizing properties, and adhesion strength with respect to a conductor, and improves the conductivity of the conductor.

To obtain a radical generating ability, the epoxy resin composition may contain at least one compound having at least one radical polymerizable double bond.

The compound having a radical polymerizable double bond and included in the epoxy resin composition may be an acrylate compound, or a methacrylate compound.

The acrylate or methacrylate compound that can be used in the invention has at least one acryloyl group, which is an ethylenic unsaturated group, in the molecule, and otherwise there is no particular limit thereto. However, the acrylate or methacrylate compound is preferably a polyfunctional monomer in view of increased curablity and strength.

The polyfunctional monomer that may be used in the invention is preferably an ester of at least one type of polyhydric alcohol and at least one of acrylic acid and methacrylic acid.

Examples of the polyhydric alcohol include ethylene glycol, 1,4-cyclohexanol, pentaerythritol, trimethylolpropane, trimethylolethane, dipentaerythritol, 1,2,4-cyclohexanol, polyurethane polyol, and polyester polyol. The polyhydric alcohol is preferably trimethylolpropane, pentaerythritol, dipentaerythritol or polyurethane polyol.

The epoxy resin layer may include two types or more of polyfunctional monomers. The polyfunctional monomer in the invention has at least two ethylenic unsaturated groups in the molecule, and preferably has at least three ethylenic unsaturated groups in the molecule.

The polyfunctional monomer may be a polyfunctional acrylate monomer having 3 to 6 acrylate groups in the molecule. Alternatively, the polyfunctional monomer may also be an oligomer having molecular weight of hundreds to thousands, having several acrylate groups in the molecule, and referred to as urethane acrylate, polyester acrylate, or epoxy acrylate, and such an oligomer can be preferably used as one of the components of an epoxy resin layer in the invention.

Specific examples of the acrylate having three or more acrylic groups in the molecule include polyol polyacrylates such as trimethylolpropane triacrylate, ditrimethylolpropane tetraacrylate, pentaerythritol triacrylate, pentaerythritol tetraacrylate, dipentaerythritol pentaacrylate, and dipentaerythritol hexaacrylate, and urethaneacrylate that can be obtained by reacting polyisocyanate with acrylate having at least one hydroxyl group such as hydroxyethyl acrylate.

To improve characteristics of the epoxy resin such as mechanical strength, heat resistance, weather resistance, flame resistance, water resistance, or electrical characteristics, the epoxy resin composition may further contain other component(s). Examples of other component(s) include paper, glass fiber, silica particles, a phenol resin, a polyimide resin, a bismaleimide triazine resin, a fluorinated resin, and a polyphenylene oxide resin. When the epoxy resin composition may further contain other component(s), the amount of such component(s) is preferably in the range of 1 to 200 parts by mass, and more preferably in the range of 10 to 80 parts by mass with respect to 100 parts by mass of the epoxy resin. When the amount is less than 1 part by mass, the above characteristics cannot be improved. When the amount is more than 200 parts by mass, the strength of the resin decreases, and graft polymerization reaction does not easily proceed.

The epoxy resin composition of the invention may contain at least one organic solvent. In this case, the epoxy resin composition is in the form of a solution or varnish.

Examples of the organic solvent include ketones such as acetone, methyl ethyl ketone, and cyclohexanone; acetates such as ethyl acetate, butyl acetate, and propylene glycol monomethyl ether acetate; aromatic hydrocarbons such as toluene and xylene; and dimethylformamide, dimethylacetamide, and N-methylpyrrolidone. The organic solvent is preferably ketone, and more preferably methyl ethyl ketone or cyclohexanone. One of these organic solvents may be used alone, or two or more of them may be used together.

The content of the organic solvent(s) in the epoxy resin composition is preferably in the range of 20 to 90 mass %, and more preferably in the range of 30 to 60 mass %.

The conductive film forming method, the conductive pattern forming method, and the multilayered wiring board manufacturing method of the invention will be described below.

The conductive film forming method of the invention includes: (a) forming an epoxy resin layer including the aforementioned thermosetting epoxy resin composition on an insulating substrate; (b) forming a graft polymer on a surface of the epoxy resin layer by applying energy to the entire surface of the epoxy resin layer and bonding a polymer having a functional group that interacts with an electroless plating catalyst or a precursor thereof to the entire surface; (c) providing the electroless plating catalyst or the precursor thereof to the graft polymer; and (d) forming a conductive film by performing electroless plating.

The conductive pattern forming method of the invention includes: (A) forming an epoxy resin layer including the aforementioned thermosetting epoxy resin composition on an insulating substrate; (B) forming a graft polymer on a surface of the epoxy resin layer by pattern-wise applying energy to the surface of the epoxy resin layer and bonding a polymer having a functional group that interacts with an electroless plating catalyst or a precursor thereof to a portion of the epoxy resin layer to which portion energy has been applied; (C) providing the electroless plating catalyst or the precursor thereof to the graft polymer; and (D) forming a conductive pattern by performing electroless plating.

The multilayered wiring board manufacturing method of the invention includes: (a′) forming an epoxy resin layer including the aforementioned thermosetting epoxy resin composition on a first conductive pattern that is formed on an insulating substrate; (b′) forming a graft polymer pattern on the epoxy resin layer by applying a compound having a double bond and a compound having a functional group that interacts with an electroless plating catalyst or a precursor thereof and pattern-wise irradiating the surface of the epoxy resin layer with ultraviolet light; (c′) forming a via hole in the epoxy resin layer before or after the graft polymer pattern is formed on the epoxy resin layer; and (d′) forming a conductive path by subjecting the epoxy resin layer to electroless plating so as to form a second conductive pattern corresponding to the graft polymer pattern and a buried via that electrically connects the first conductive pattern with the second conductive pattern.

Hereinafter, the conductive film forming method, the conductive pattern forming method, and the multilayered wiring board manufacturing method of the invention will be described in more detail.

Since the step (a) of the conductive film forming method and the step (A) of the conductive pattern forming method are the same as the step (a′) of the multilayered wiring board manufacturing method, explanations for the steps (a) and (A) will be described together with those for the step (a′).

Likewise, since the step (B) of the conductive pattern forming method is the same as the step (b′) of the multilayered wiring board manufacturing method, explanations for the steps (B) will be described together with those for the step (b′).

The step (b) of the conductive film forming method and the step (b′) of the multilayered wiring board manufacturing method are different from each other in that ultraviolet light is irradiated on the entire surface of the epoxy resin layer to form a graft polymer on the entire surface in the former step and is pattern-wise irradiated to the epoxy resin layer to form a graft polymer pattern in the latter step. However, otherwise these steps are the same. Accordingly, explanations for the steps (b) will be described together with those for the step (b′).

The steps (c) and (d) of the conductive film forming method, and the steps (C) and (D) of the conductive pattern forming method are the same as the step (d′) of the multilayered wiring board manufacturing method, except for the following differences.

In the step (d′) of the multilayered wiring board manufacturing method, the epoxy resin layer is subjected to electroless plating so as to form a second conductive pattern corresponding to the graft polymer pattern and at least one buried via that electrically connects the first conductive pattern with the second conductive pattern and to thereby form a conductive path. In contrast, a buried via and a conductive path are not formed and a conductive film or pattern is formed by electroless plating only on the graft polymer in the steps (c) and (d) of the conductive film forming method, and the steps (C) and (D) of the conductive pattern forming method. However, explanations for the steps (c), (d), (C) and (D) will be described together with those for the step (d′).

In the conductive film forming method, the conductive pattern forming method, and the multilayered wiring board manufacturing method, an insulating substrate is provided at first.

Examples of the insulating substrate include metal plates (for example, aluminum, zinc, and copper plates), a silicon substrate, plastic films (for example, cellulose diacetate, cellulose triacetate, cellulose propionate, cellulose butyrate, cellulose acetate butyrate, cellulose nitrate, polyethylene terephthalate, polyethylene, polystyrene, polypropylene, polycarbonate, polyvinyl acetal, polyimide, and epoxy resin films), and rigid insulating substrates (for example, glass epoxy substrate). One of these substrates may be used alone, or two or more of them may be used as a composite substrate. Examples of the composite substrate include epoxy substrates and plastic films on each of which at least one metal film is laminated or deposited, and a substrate having epoxy layers and metal films or patterns each disposed between the epoxy layers. The substrate is preferably a polyimide film or an epoxy substrate including an epoxy resin as the main component. The insulating substrate used to manufacture a multilayered wiring board preferably includes an epoxy resin as the main component.

The insulating substrate used in the invention preferably has excellent surface smoothness. The Rz value (ten-point average height stipulated in JIS B0601) of the insulating substrate is preferably 3 μm or less, and more preferably 1 μm or less. When the insulating substrate and the epoxy resin layer have surface smoothness within the above range, and, in other words, when the insulating substrate and the epoxy resin layer do not substantially have unevenness, it is possible to form highly precise wiring on the epoxy resin. This is applicable even to a case where wiring is extremely fine. Accordingly, it is possible to manufacture a wiring board having a high-density and highly precise electric circuit.

The epoxy resin used in the substrate having an epoxy resin as the main component may be the same as that of the epoxy resin layer described previously. Such an epoxy resin substrate may further contain any other resin(s), at least one reinforcing material and/or at least one filler, such as paper, glass fiber and silica particles.

In the multilayered wiring board manufacturing method of the invention, a first conductive pattern is formed on the insulating substrate to form a laminated body.

The first conductive pattern may be formed by any method. For example, a copper-clad laminate is etched to form a copper pattern or a copper pattern is formed by using a resist and electroless plating in a known method. Alternatively, the first conductive pattern may be formed by using a graft polymer pattern as in a second conductive pattern, which will be described later.

In the step (a′) of the multilayered wiring board manufacturing method of the invention, an epoxy resin layer is formed on the first conductive pattern that is disposed on the insulating substrate.

An epoxy resin layer is formed on the insulating substrate in the step (a) of the conductive film forming method and the step (A) of the conductive pattern forming method of the invention.

The epoxy resin layer can be formed by applying a curable epoxy resin composition to the insulating substrate and the first conductive pattern according to a known method such as a screen printing method, a spray method, or a curtain coating method, and drying, heating and curing the resultant coating, or by laminating an epoxy resin film on the insulating substrate and the first conductive pattern, and heating and curing the epoxy resin film.

Before the epoxy resin layer is formed, the epoxy resin may be introduced into recess portions present in the first conductive pattern to flat the surface of the first conductive pattern. In this case, the epoxy resin layer provided on the first conductive pattern also has a flat surface, which makes it possible to conduct subsequent steps with high reliability.

Preferably, the temperature and the time to heat and cure the epoxy resin composition are in the range of 150° C. to 220° C. and in the range of 10 to 180 minutes, respectively. More preferably, the temperature and the time are in the range of 160° C. to 200° C. and in the range of 20 to 120 minutes, respectively.

The glass-transition temperature Tg of the epoxy resin layer obtained by using the epoxy resin composition is preferably in the range of 150° C. to 230° C., and more preferably in the range of 150° C. to 180° C.

When the Tg of the epoxy resin layer is less than 150° C., the dimensional difference between an uncured epoxy resin layer and a cured epoxy resin layer is big and such an epoxy resin layer has deteriorated resistance to heat due to soldering. When the Tg of the epoxy resin layer is more than 230° C., the cured epoxy resin layer tends to be brittle and has a high water-absorbing property, which are at the sacrifice of obtaining heat resistance.

The insulating resin having a glass-transition temperature Tg within the above range is, for example, a thermosetting resin, and specific examples of the thermosetting resin include an epoxy resin, a bismaleimide resin, and a cyanate resin.

The glass-transition temperature Tg can be obtained by, for example, TMA method. In this method, a specimen is heated at a programming rate of 5° C./minute, and the thermal expansion amount of the specimen in its thickness direction is measured with a thermal analyzer. Then, a curve showing the relationship between temperature and thermal expansion amount is drawn according to the measured values. A tangent is drawn on the curve at each of points respectively disposed before and after a point at which a coefficient of thermal expansion changes, and the point at which these tangents intersect with each other is regarded as the glass-transition temperature of the specimen.

The coefficient of linear thermal expansion of the epoxy resin layer used to manufacture a multilayered wiring board, a conductive film, and/or a conductive pattern in the invention is preferably in the range of 20 ppm to 80 ppm, and more preferably in the range of 20 ppm to 40 ppm at a temperature equal to or less than the glass-transition temperature Tg.

When the coefficient of linear thermal expansion of the insulating resin layer is higher than 80 ppm, the dimensional difference between an unheated insulating resin layer and a heated insulating resin layer is big, which generates big stress. For these reasons, such an insulating resin layer has decreased crack resistance. When the coefficient of linear thermal expansion of the insulating resin layer is less than 20 ppm, the same problems occur.

The epoxy resin composition preferably contains at least one inorganic filler such as silica in view of a reduction in a thermal expansion coefficient.

The coefficient of linear thermal expansion is measured by, for example, Thermal Mechanical Analysis (TMA) method under the following measurement conditions. A specimen having a width of 4 mm and a length of 30 mm is cut from an epoxy resin layer. The specimen is used in measurement conducted with a device (i.e., TMAQ400 manufactured by TA Instruments) and a load of 0.03 N at a distance between chucks of 15 mm at a programming rate of 5° C./minute within the temperature range of 25° C. to 250° C. The coefficient of linear thermal expansion of the specimen at a temperature equal to or less than the glass-transition temperature is obtained from the measurement results.

To improve crack resistance of the epoxy resin layer, stress may be reduced. To achieve this, it is preferable to use an epoxy resin having large elongation at break in the insulating resin layer. The elongation at break, measured by a tension tester, of the epoxy resin is preferably in the range of 5 to 15%, and more preferably in the range of 8 to 12%.

The tension tester used to measure the elongation at break of the epoxy resin layer may be TENSILON (RPM-50 manufactured by Orientec, Co., Ltd.)

The epoxy resin composition preferably contains at least one thermoplastic resin as well as the epoxy resin in order to achieve elongation at break within the above range. Specific examples of the thermoplastic resin include polyethersulfone, phenoxy resin, and PPE.

A solder having a high melting point and not including lead is becoming mainstream due to legislative restrictions regarding environmental protection in the fields of sealing materials for semiconductors and wiring boards. For this reason, for example, a reflow temperature at which a semiconductor is packaged has become higher than a conventional reflow temperature, easily generating cracks in an insulating layer. To address this, there is a need for an epoxy resin having a lower thermal expansion coefficient to improve heat resistance thereof and to reduce stress generated.

Selecting the type of an epoxy resin composition used to form an epoxy resin layer to obtain a glass-transition temperature Tg, a coefficient of linear thermal expansion and elongation at beak within the respective ranges makes it possible to realize a reduced thermal expansion coefficient that improves heat resistance of the epoxy resin layer and reduces stress generated.

When a metal pattern is used as wiring (conductive film) for multilayered wiring board manufactured by the method of the invention, decreasing the dielectric constant and the dielectric dissipation factor of materials is effective in suppressing delay and damping of signals and thereby processing a large capacity of data at a high speed.

Use of materials having low dielectric dissipation factor is specifically described in ELECTRONICS PACKAGING INSTITUTIONAL JOURNAL” vol. 7, No. 5, pp. 397 (2004). An insulating material having low dielectric dissipation factor is preferably used from the viewpoint of data processing at a higher speed.

The dielectric constant (relative dielectric constant) of the epoxy resin composition used to manufacture a multilayered wiring board, a conductive film, and a conductive pattern in the invention at 1 GHz is preferably in the range of 2.5 to 3.5, and more preferably in the range from 2.5 to 3.1.

The dielectric dissipation factor of the epoxy resin composition at 1 GHz is preferably in the range of 0.004 to 0.03, and more preferably in the range of 0.004 to 0.028.

The dielectric constant and dielectric dissipation factor of the epoxy resin layer can be measured by a conventional method, for example, a method described in the Abstracts of 18^{th} JIEP Annual Meeting, 2004, p 189, in which device and system for measuring εr and tan δ of an ultra thin sheet manufactured by Keycom Co., Ltd and using a cavity resonator perturbation method are used.

The epoxy resin layer in the invention can be obtained by applying and curing an epoxy resin composition that is so selected as to satisfy the above physical properties. There is no particular limit to the thickness of the epoxy resin layer and a desired thickness for the epoxy resin layer is appropriately selected according to the object of the conductive film or pattern. Generally, the thickness of the epoxy resin layer is in the range of 10 to 200 μm.

A surface graft polymer is easily formed on the epoxy resin layer in the invention by bringing at least one compound each having at least one double bond into contact with the epoxy resin layer and applying energy to the compound adhering to the epoxy resin layer without performing surface activation processing in which high energy is applied to the epoxy resin layer and which is often performed to increase adhesion between a circuit and the epoxy resin layer, such as electron ray irradiation, plasma irradiation, or glow processing. This is because the epoxy resin composition has the aforementioned characteristics. In consideration of the characteristics of a surface graft polymer to be obtained, it is preferable that the epoxy resin layer has a smooth surface. To attain this, it is preferable that the surface of the resin layer in the invention is not subjected to any surface processing and preprocessing.

Specifically, the surface of the epoxy resin layer preferably has smoothness in which the average roughness (Rz), measured by a ten-point average height measuring method stipulated in JIS B0601 (1994), of the layer is 3 μm or less, as described above.

### Adhesive Layer

When a first circuit (first conductive pattern) is formed on an insulating substrate and wiring (multilayered wiring layers) is formed on the first circuit by a build-up method in the multilayered wiring board manufacturing method of the invention, an adhesive layer may be provided between the first conductive pattern and an epoxy resin layer to be formed on the first conductive pattern in order to increase adhesion therebetween.

A conventional adhesive resin may be used to form the adhesive layer. If strong adhesion and suitable fluidity of a resin can be realized, a known technique may be used. The adhesive layer may be a conductive adhesive layer including suitable conductive particles such as metal microparticles.

There is no particular limit to the type of the material for the adhesive layer. Adhesive resins contained in adhesive layers are roughly classified into two groups: (A) thermally fusable adhesives including a thermoplastic resin and (B) curable adhesives using curing reaction of a thermosetting resin.

Next, a graft polymer is formed in the step (b) of the conductive film forming method, the step (B) of the conductive pattern forming method, and the step (b′) of the multilayered wiring board manufacturing method.

In the multilayered wiring board manufacturing method of the invention, the step (c′) of forming a via hole in the epoxy resin layer, which will be described later in detail, is carried out before or after the step (b′).

In formation of a graft polymer in the steps (b), (b′), and (B), at least one compound each having at least one double bond is brought into contact with the surface of the epoxy resin layer, and energy such as ultraviolet light is applied to the compound adhering to the epoxy resin layer. When energy is applied, a graft polymer pattern directly bonding to the surface of the epoxy resin layer is formed only in a portion of the epoxy resin layer to which energy is applied.

Hereinafter, a method for forming a graft polymer pattern will be described in detail.

### Surface Graft Polymer Forming Method

In the conductive film forming method, the conductive pattern forming method, and the multilayered wiring board manufacturing method of the invention, a graft polymer directly bonded to the surface of the epoxy resin layer is produced by applying at least one compound each having at least one double bond to the surface of the epoxy resin layer and applying energy to the surface of the epoxy resin layer by irradiating ultraviolet light, as described above.

### Double Bond Compound

Each of the at least one compound each having at least one double bond and applied to the surface of the epoxy resin layer may be a monomer or a macromer having at least one polymerizable group, or a high molecular weight compound having at least one double bond. Any known compound can be used as such. A compound having at least one polymerizable group and at least one polar functional group is useful as the compound having at least one double bond in the invention. A graft polymer to be formed may be hydrophilic and may interact with an electroless plating catalyst or a precursor thereof due to the graft polymer having such a polar functional group. The polar functional group may be a hydrophilic group and examples thereof include a carboxyl group, a hydroxyl group, an amino group, a sulfonic group, a phosphonic group, and an amido group.

The monomer having at least one double bond, which is applied to the surface of the epoxy resin layer, is, for example, (meth)acrylate with an alkyl group having 1 to 24 carbon atoms. Examples thereof include (meth)acrylic acid and alkali metal salts and amine salts thereof, itaconic acid and alkali metal salts and amine salts thereof, styrenesulfonic acid and alkali metal salts and amine salts thereof, 2-sulfoethyl(meth)acrylate and alkali metal salts and amine salts thereof, 2-acrylamide 2-methylpropanesulfonate and alkali metal salts and amine salts thereof, acid phosphooxypolyoxyethylene glycol mono(meth)acrylate and alkali metal salts and amine salts thereof, polyoxyethylene glycol mono(meth)acrylate, 2-hydroxyethyl(meth)acrylate, (meth)acrylamide, N-monomethylol(meth)acrylamide, N-dimethylol(meth)acrylamide, allylamine and hydrohalic acid salts thereof, N-vinylpyrrolidone, vinylimidazole, vinylpyridine, vinylthiophene, styrene, ethyl (meth)acrylate, and n-butyl(meth)acrylate.

In addition to the monomer, a macromer or polymer can also be preferably used as the compound having at least one double bond and applied to the surface of the epoxy resin layer, as described above. The macromer having at least one double bond can be produced by polymerizing at least one of the above monomers in accordance with a known method. A method for producing the macromonomer may be selected from various producing methods suggested in the second chapter “Synthesis of Macromonomer” of CHEMISTRY AND INDUSTRY OF MACROMONOMER edited by Yuya Yamashita and published by IPC (Sep. 20, 1989). The weight-average molecular weight of the macromonomer is preferably 250 to 100,000, and more preferably 400 to 30,000.

In the invention, the high molecular weight compound having at least one double bond which can be applied to the surface of the epoxy resin layer is a polymer having, as at least one polymerizable group, at least one ethylenic addition-polymerizable unsaturated group such as a vinyl group, an allyl group, or an (meth)acrylic group. The polymer has at least one polymerizable group at one or more of terminals and the side chains, and preferably has at least one polymerizable group on or in the side chain(s).

The high molecular weight compound having at least one double bond has preferably at least one polar group such as a carboxyl group, or at least one functional group capable of interacting with at least one functional material to be bonded to the surface of the epoxy resin layer.

The weight-average molecular weight of the high molecular weight compound having at least one polymerizable group is preferably in the range of 500 to 500,000, and more preferably in the range of 1,000 to 50,000.

A graft polymer forming density is increased and a uniform and high-density graft polymer is formed by using the macromer or polymer having polymerizable groups at the terminal or terminals and on or in the side chain(s) as a compound having at least one double bond and applied to the surface of the epoxy resin layer. Accordingly, when the electroless plating catalyst or the precursor thereof is provided to the surface graft polymer, an adhesion density between the graft polymer and the catalyst or precursor is increased and an excellent plating accepting area can be obtained. When the macromer or the polymer, which has polymerizable groups at a high density, is used as the compound having at least one double bond to form a graft polymer by a known method in which a polymerization initiator is used or high-energy electron beams are used, a homopolymer, which has reduced removability, is substantially produced. Accordingly, it is found that use of such a compound having at least one double bond makes the effect of the invention remarkable.

In view of a producing method, when the surface of the epoxy resin layer is brought into contact with the polymer serving as the compound having at least one double bond by an application method, a high molecular weight coating film having an even and desired thickness is easily formed. This is because a protection cover necessary to apply a coating solution including a monomer is unnecessary. As a result, a graft polymer formed has improved evenness. Thus, use of a polymer is suitable for large-area conductive film production or mass production.

The high molecular weight compound having at least one functional group (interactive group) and at least one double bond can be synthesized by copolymerizing at least one monomer each having at least one functional group and at least one monomer each having at least one polymerizable group (method (i)); copolymerizing at least one monomer each having at least one functional group and at least one monomer each having at least one double bond precursor site, and processing the double bond precursor site with, for example, a base to introduce double bonds into the resultant copolymer (method (ii)); or reacting at least one polymer having functional groups with at least one monomer each having at least one polymerizable group to introduce double bonds (i.e., polymerizable groups) to the polymer (method (iii)).

The high molecular weight compound having at least one functional group and at least one double bond is preferably synthesized by method (ii) or (iii) from the viewpoint of synthesis suitability.

Examples of the monomer having at least one functional (interactive) group used for preparation of a graft polymer include (meth)acrylic acid and alkali metal salts and amine salts thereof, itaconic acid and alkali metal salts and amine salts thereof, 2-hydroxyethyl (meth)acrylate, (meth)acrylamide, N-monomethylol (meth)acrylamide, N-dimethylol (meth)acrylamide, allylamine and hydrohalic acid salts thereof, 3-vinylpropionic acid and alkali metals and amine salts thereof, vinylsulfonic acid and alkali metals and amine salts thereof, 2-sulfoethyl(meth)acrylate, polyoxyethylene glycol mono(meth)acrylate, 2-acrylamide-2-methypropanesulfonic acid, acid phosphoxy polyoxyethylene glycol mono(meth)acrylate, N-vinylpyrrolidone (the following structure), sodium styrenesulfonate, and vinylbenzoic acid. Generally, any of monomers having at least one functional group such as a carboxyl group, a sulfonic group, a phosphonic group, an amino group or a salt thereof, a hydroxyl group, an amido group, a phosphine group, an imidazole group, a pyridine group or a salt thereof, or an ether group may be used as such.

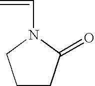

The monomer having at least one polymerizable group to be copolymerized with the monomer having at least one functional (interactive) group may be allyl(meth)acrylate or 2-allyloxyethyl methacrylate.

The monomer having at least one double bond precursor site may be 2-(3-chloro-1-oxopropoxy)ethyl methacrylate or any of compounds (i-1 to i-60) described in JP-A No. 2003-335814, and is preferably the following compound (i-1).

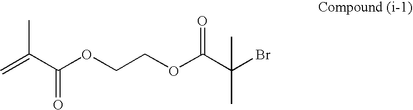

Examples of the monomer having at least one polymerizable group used to introduce unsaturated groups into a polymer having functional (interactive) groups, which react with the polymerizable group, such as a carboxyl group, an amino group or a salt thereof, a hydroxyl group or an epoxy group include (meth)acrylic acid, glycidyl(meth)acrylate, allyl glycidyl ether, and 2-isocyanatoethyl(meth)acrylate.

The method (ii) of copolymerizing at least one monomer each having at least one functional group and at least one monomer each having at least one double bond precursor site, and processing the double bond precursor site with, for example, a base to introduce double bonds into the resultant copolymer may be a method described in JP-A No. 2003-335814.

### Surface Graft Polymerization

A graft polymer formed on the surface of an epoxy resin layer is generally produced by surface graft polymerization.

Graft polymerization is synthesis of a graft polymer by providing active species, which initiate polymerization of a monomer, onto a high molecular weight compound chain, and polymerizing the monomer. When the high molecular weight compound onto which the active species are provided forms a solid surface, such polymerization is particularly referred to as surface graft polymerization.

In the invention, at least one compound each having at least one double bond (polymerizable group) is brought into contact with the surface of an epoxy resin layer obtained by using the epoxy resin composition of the invention, energy is applied to the at least one compound adhering to the surface to generate active points, and the active points are reacted with the polymerizable group of the compound to cause surface graft polymerization reaction. Here, the photopolymerization initiator contained in the epoxy resin composition functions as an initiator for the surface graft polymerization.

The compound having at least one double bond may be brought into contact with the surface of the epoxy resin layer containing an epoxy resin by immersing an insulating substrate having thereon an epoxy resin layer, or an insulating substrate having thereon a first conductive pattern and an epoxy resin layer in a liquid composition containing the compound having at least one double bond. However, it is preferable to apply the compound having at least one double bond, or a composition containing the compound having at least one double bond as the main component to the surface of the epoxy resin layer so as to form a layer including the compound having at least one double bond on the surface of the epoxy resin layer in consideration of a handling property, production efficiency, or influence on a circuit to be formed.

To suppress undesired production of a homopolymer, it is preferable that the compound having at least one double bond is brought into contact with the surface of the epoxy resin layer in the absence of a compound having a polymerization initiation ability. When only the compound having at least one double bond is brought into contact with the surface of the epoxy resin layer, other compound does not coexist on the surface. However, when the compound having at least one double bond is dissolved or dispersed in a solvent and the surface is brought into contact with the resultant solution or dispersion, it is necessary that the solution or dispersion contain no compound that is concerned with polymerization reaction, such as a polymerization initiator.

Accordingly, it is preferable that the composition containing the compound having at least one double bond and used in the immersion or application includes only the compound having at least one double bond as the main component and a solvent or a dispersion medium. Even if the composition includes other compound(s), it is preferable that the other compound(s) is limited to a surfactant for increasing the physical properties of the liquid composition, such as an application property or a surface property. When the composition is applied to the epoxy resin layer, the resultant coating is preferably dried to remove the solvent before light irradiation.

It is necessary that the compound having at least one polymerizable group and that having at least one functional (interactive) group serving as the main components of the composition are dissolved or dispersed in the solvent contained in the composition, and otherwise there is no particular limit to the solvent. The solvent is preferably an aqueous solvent such as water or a water-soluble solvent. The composition may further contain at least one surfactant.

Examples of the solvent include alcoholic solvents such as methanol, ethanol, propanol, ethylene glycol, glycerin, and propylene glycol monomethyl ether; acids such as acetic acid; ketone solvents such as acetone and cyclohexanone; and amide solvents such as formamide and dimethylacetamide.

It is necessary that the surfactant which is contained in the composition, as needed, is soluble in the solvent, and otherwise there is no particular limit to the surfactant. Examples of the surfactant include anionic surfactants such as sodium n-dodecylbenzenesulfonate; cationic surfactants such as n-dodecyl trimethyl ammonium chloride; nonionic surfactants such as polyoxyethylene nonyl phenol ether (e.g., EMULGEN 910 manufactured by Kao Corporation), polyoxyethylene sorbitan monolaurate (e.g., TWEEN 20), and polyoxyethylene lauryl ether.

When the epoxy resin layer is immersed in the liquid composition, there is no particular limit to the thickness of the resultant coating. However, to obtain a satisfactory coating film in applying the composition to the surface of the epoxy resin layer, the amount of the solid matter of the composition applied is preferably in the range of 0.1 to 10 g/m², and more preferably in the range of 0.5 to 5 g/m².

### Energy Application

Energy can be applied to the compound having at least one double bond and adhering to the epoxy resin layer to generate active points and to produce a graft polymer from the active points by irradiating ultraviolet light or radiation rays such as γ-rays or electron beams. For example, the irradiation can be performed by using a UV lamp, or a black light.

In addition to these, a mercury lamp, a metal halide lamp, a xenon lamp, a chemical lamp or a carbon arc lamp may also be used as a light source. Also, g-rays, i-rays and Deep-UV rays may be used as light to be irradiated.

The time necessary to apply energy depends on the amount of the graft polymer to be produced and the type of the light source. However, the time is usually in the range of 10 second to 5 hours.

Energy is applied to the epoxy resin layer by irradiating the entire surface of the epoxy resin layer with light emitted by the light source or by pattern-wise irradiating the epoxy resin layer with light.

To form a high-definition pattern, the light source is preferably a (low-pressure, medium-pressure, high-pressure, or ultra high-pressure) mercury lamp that can emit parallel light beams having wavelengths of 254 nm and 365 nm, and the irradiating method is generally a contact aligner method in which parallel light beams are irradiated. Alternatively, the irradiating method may be a light beam scanning exposure method using an optical system, or an irradiating method using a mask. The irradiating method can be selected according to the resolution of a desired pattern. Specifically, a mask film having openings for a pattern is brought into close contact with the epoxy resin layer and the epoxy resin layer is exposed to light via the mask film in some cases. Alternatively, the epoxy resin layer is scanned in some cases. When a parallel light source emitting ultraviolet light, which has relatively short wavelengths, and a mask with openings for a pattern having a line width of 100 μm or less, preferably 3 to 25 μm, are used, it is possible to form a high-definition pattern corresponding to the mask film.

A graft polymer pattern is formed by cleaning the substrate having thereon an epoxy resin that has been exposed to light with a solvent, such as water, to remove the un-reacted portion of the compound having at least one double bond. A homopolymer, which is undesirable in the invention, is not formed, and impurities are easily removed by using a simple cleaning process in the method of the invention. As a result, a high-definition graft polymer pattern according to the irradiation conditions can be formed.

The thickness of the resultant graft polymer film is preferably such that the amount of the graft polymer film is in the range of 0.1 to 2.0 g/m². The amount is more preferably in the range of 0.3 to 1.0 g/m², and most preferably in the range of 0.5 to 1.0 g/m².

Since the graft polymer pattern-formed area has at least one functional group such as a polar group or an interactive group with respect to an electroless plating catalyst or a precursor thereof, the area has an excellent plating accepting property in conducting electroless plating.

In the step (c′) of the multilayered wiring board manufacturing method of the invention, at least one via hole to form at least one buried via that serves as a part of a conductive path and that electrically connects a second conductive pattern described later and the first conductive pattern is formed in the epoxy resin layer before or after the step (b′).

The at least one via hole can be formed with a known device, such as a drill machine, a dry plasma apparatus, a carbon dioxide gas laser, a UV laser or an excimer laser. However, the formation is preferably conducted by using a UV-YAG laser, or an excimer laser to enable formation of a via hole having a small diameter and a good shape. When the at least one via hole is formed by irradiating the epoxy resin layer with laser beams emitted by, for example, a carbon dioxide gas laser to heat and decompose the layer, it is preferable to perform a desmear process. By performing the desmear process, a better conductive layer can be formed in the via hole in a subsequent process.

Next, the steps (c) and (d) of the conductive film forming method, the steps (C) and (D) of the conductive pattern forming method, and the step (d′) of the multilayered wiring board manufacturing method will be described.

In the step (c) of the conductive film forming method, the step (C) of the conductive pattern forming method, and the step (d′) of the multilayered wiring board manufacturing method, an electroless plating catalyst or a precursor thereof is provided to the graft polymer. Moreover, in the step (d) of the conductive film forming method, and the step (D) of the conductive pattern forming method, electroless plating is performed to form a conductive film or a conductive pattern.

An area in which the graft polymer is formed on the epoxy resin layer (graft polymer-formed area) serves as a plating accepting area. Electroless plating is selectively performed only on the graft polymer-formed area. When the graft polymer is formed on the entire surface of the epoxy resin layer, a conductive film is formed. When the graft polymer is pattern-wise formed on the surface of the epoxy resin layer, a conductive pattern is formed.

In the step (d′) of the multilayered wiring board manufacturing method of the invention, electroless plating is conducted to simultaneously form a second conductive pattern corresponding to the graft polymer pattern and at least one buried via that electrically connects the first conductive pattern and the second conductive pattern. Thus, a conductive path is formed.

In the plating process performed in this step, there is no particular limit to the type of a metal used, and known electroless plating such as copper plating or nickel plating can be carried out.

To conduct the electroless plating process, an electroless plating catalyst or a precursor thereof can be provided to the graft polymer (chain)-formed area (graft pattern), and electroless plating process can be conducted to form a metal film in the form of a pattern.

### <Electroless Plating Catalyst>

The electroless plating catalyst used in this step is mainly a zero-valent metal such as Pd, Ag, Cu, Ni, Al, Fe, or Co. The electroless plating catalyst is preferably Pd or Ag in the invention because of a good handling property and high catalytic ability thereof. To fix the zero-valent metal on the graft polymer pattern, a metal colloid having a charge so adjusted as to enable interaction to the functional groups of the graft polymer pattern which functional groups interact with the electroless plating catalyst or the precursor thereof is provided to the graft polymer pattern. The metal colloid can be produced by preparing a solution that includes metal ions and at least one surfactant or protective agent having a charge, and reducing the metal ions in the solution. The charge of the metal colloid can be adjusted with the surfactant or the protective agent. Such metal colloid having an adjusted charge is allowed to interact with the functional groups that the graft pattern. Thus, the metal colloid (electroless plating catalyst) can be selectively adsorbed by the graft polymer pattern.

### <Electroless Plating Catalyst Precursor>

The electroless plating catalyst precursor used in this step is any of substances that can become an electroless plating catalyst by chemical reaction. The ions of the zero-valent metal used as the electroless plating catalyst are mainly used as such. The metal ions serving as the electroless plating catalyst precursor are reduced to become a zero-valent metal serving as an electroless plating catalyst. The metal ions may be applied to the graft polymer pattern on the epoxy resin layer disposed on a substrate and reduced into a zero-valent metal serving as an electroless plating catalyst, and the substrate may be immersed in an electroless plating bath. Alternatively, the metal ions may be applied to the graft polymer pattern on the epoxy resin layer disposed on a substrate, and the substrate may be immersed in an electroless plating bath including at least one reducing agent to reduce the metal ions into a zero-valent metal (electroless plating catalyst) and conduct electroless plating.

Practically, the metal ions serving as the electroless plating precursor are used in the form of a metal salt, and the metal salt is added to the graft polymer pattern. It is necessary that the metal salt be soluble in a suitable solvent to dissociate into metal ions and a base (anion), and otherwise there is no particular limit to the metal salt. Examples thereof include M(NO₃)ₙ, MClₙ M_{2/n}(SO₄), and M_{3/n}(PO₄). M is an n-valent metal ion. Specific examples of the metal ions include Ag ions, Cu ions, Al ions, Ni ions, Co ions, Fe ions, and Pd ions. The metal ions are preferably Ag ions and/or Pd ions from the viewpoint of catalytic ability.

The metal colloid serving as an electroless plating catalyst or the metal salt serving as an electroless plating precursor can be provided to the graft polymer pattern as follows. The metal colloid is dispersed in a suitable dispersion medium, or the metal salt is dissolved in a suitable solvent to prepare a dispersion or solution that contains metal ions obtained by dissociating the metal colloid or the metal salt. The dispersion or solution is applied to the graft polymer pattern, or a substrate having thereon the graft polymer pattern is immersed in the dispersion or solution. Bringing the graft polymer pattern into contact with the dispersion or solution containing metal ions causes the metal ions to be adsorbed by the functional (interactive) groups on the graft polymer-formed area or to be impregnated into the graft polymer-formed area due to ion-ion interaction or dipole-ion interaction. To sufficiently conduct the adsorption or impregnation, the concentration of the metal ions or salt in the dispersion or solution is preferably in the range of 1 to 50% by mass and more preferably 10 to 30% by mass. In addition, the contact time is preferably about 1 minute to 24 hours and more preferably about 5 minutes to 1 hour.

By performing the electroless plating with respect to the graft polymer-formed area that is disposed on the epoxy resin layer formed on the insulating substrate and where the electroless plating catalyst or precursor thereof has been adsorbed, a high-density metal film corresponding to the graft polymer pattern is formed on the graft polymer pattern obtained in the foregoing step to produce a second conductive pattern. As a result, the second conductive pattern has excellent conductivity and strong adhesion with respect to the epoxy resin layer.

### <Electroless Plating>

The electroless plating is an operation of depositing a metal in a solution where the ions of the metal are dissolved by chemical reaction.

The electroless plating in this step is conducted by, for example, cleaning a substrate having thereon an epoxy resin layer and a graft polymer pattern to which an electroless plating catalyst has been provided with water to remove the excess portion of the electroless plating catalyst (e.g., metal), and immersing the substrate in an electroless plating bath. The electroless plating bath may have a generally known composition.

When a substrate has thereon an epoxy resin layer and a graft polymer pattern where an electroless plating catalyst precursor has been adsorbed or impregnated, the substrate is cleaned with water to remove the excess portion of the electroless plating catalyst precursor (e.g., metal salt), and is immersed in an electroless plating bath. In this case, the precursor is reduced and the electroless plating is subsequently performed in the electroless plating bath. The electroless plating bath may have a generally known composition.

The electroless plating bath mainly includes (1) metal ions for plating, (2) at least one reducing agent, and (3) at least one additive (stabilizer) for improving stability of the metal ions. The electroless plating bath may further include known other additives such as a stabilizer for a plating bath.

Examples of the metal to be used in the electroless plating bath include copper, tin, lead, nickel, gold, palladium, and rhodium. The metal is preferably copper or gold from the viewpoint of good conductivity.

The reducing agent(s) and the additive(s) are so selected as to be optimum to the type of the metal. For example, a copper electroless plating bath includes Cu(SO₄)₂ as a copper salt, HCOH as a reducing agent, and, as an additive, EDTA, which is a stabilizer for copper ions, or a chelating agent such as a rochelle salt. A CoNiP electroless plating bath includes cobalt sulfate and nickel sulfate as metal salts, sodium hypophosphite as a reducing agent, and sodium malonate, sodium malate, and sodium succinate as complexing agents. A palladium electroless plating bath includes (Pd(NH₃)₄)Cl₂ as metal ions, NH₃, and H₂NNH₂ as reducing agents, and EDTA as a stabilizer. These plating baths may further include other component(s).

The thickness of the metal film thus formed can be controlled by controlling the concentration of the metal salt or the metal ions in the plating bath, the immersion time in the plating bath, and/or the temperature of the plating bath. The thickness of the metal film is preferably 0.5 μm or more, and more preferably 0.3 μm or more in view of conductivity.

The immersion time in the plating bath is preferably in the range of about 1 minute to 3 hours, and more preferably in the range of about 1 minute to 1 hour.

### Electroplating Process

Electroplating can be carried out after the electroless plating in the invention. The metal film formed by performing the electroless plating is used as an electrode in carrying out the electroplating. In this case, it is possible to easily form a metal pattern having a desired thickness on a metal (conductive) pattern having strong adhesion with respect to a substrate. Namely, this step enables formation of a metal (conductive) pattern having a desired thickness and characteristics according to, for example, the object of the wiring board.

The electroplating can be conducted by a conventionally known method. Examples of the metal used in the electroplating include copper, chromium, lead, nickel, gold, silver, tin, and zinc. The metal is preferably copper, gold, or silver, and more preferably copper in view of conductivity.

A desired thickness for the metal film obtained by the electroplating depends on usage of a wiring board serving as a final product. The thickness of the metal film can be controlled by adjusting the concentration of the metal in the plating bath, the immersion time, and/or electric current density. When the wiring board is used as an ordinary electric wiring, the thickness of the metal film is preferably 0.3 μm or more, and more preferably 3 μm or more from the viewpoint of conductivity.

According to the multilayered wiring board manufacturing method, a second conductive pattern made of a conductive material is chemically bonded to a graft polymer pattern, which has strong adhesion to an epoxy resin layer obtained by using the epoxy resin composition of the invention and having strong adhesion to a substrate. Accordingly, the adhesion strength of the epoxy resin layer and the second conductive pattern is practically high, even when an insulating substrate and an epoxy resin layer provided thereon have a high degree of smoothness.

Moreover, the at least one via hole formed in the step (c) is filled with the conductive material to produce at least one buried via in this step. In other words, formation of the second conductive pattern and formation of the buried via, which electrically connects the first conductive pattern with the second conductive pattern, are simultaneously conducted to form a conductive path. Specific examples of the conductive material include metal materials including metal elements such as copper, nickel, chromium, titanium, aluminum, molybdenum, tungsten, zinc, tin, indium, gold, and silver, and alloys thereof (e.g., nichrome); conductive high molecular weight materials such as polypyrrole, and polythiophene; and non-metal inorganic conductive materials such as graphite, and conductive ceramic.

The via hole is filled with the conductive material by an electroless plating method or an application method. According to these methods, micro space such as the space in a via hole can be relatively uniformly and easily filled with a conductive material.

For example, when the buried via is made of at least one of the aforementioned metal materials, it is preferable to provide a catalyst to the interior of a via hole and conduct chemical metal plating (electroless plating). When metal plating is performed on the surface of a graft polymer, it is preferable to simultaneously perform the metal plating in the via hole.

When the buried via is made of at least one conductive high molecular weight material, an electroless plating method or an application method is adopted to form the buried via. In the electroless plating method, an appropriate oxidizer may be provided to the interior of a via hole formed in a laminated body and the laminated body may be then immersed in a solution including pyrrole or thiophene serving as a monomer. In the application method, a solution obtained by dissolving a conductive high molecular weight material such as polypyrrole or poly-1,4-dioxithiophene in a solvent may be applied to a graft polymer layer and the inner portion of a via hole.

When the buried via is made of at least one non-metal inorganic conductive material such as graphite, an electroless plating method without using a catalyst is preferably adopted. For example, to conduct graphite plating, the surface of a via hole formed in a laminated body may be treated with a preprocess liquid and the laminated body may be immersed in a graphite dispersion liquid. A graphite plating liquid usable in the process is typically DIRECT PLATING (registered trade name) produced by Mec Co., Ltd. The graphite plating liquid is a set of a preprocess liquid (MEC S PROCESS SP-6560) and a graphite dispersion liquid (MEC S PROCESS SP-6601)

To manufacture a multilayered wiring board having three or more layers, steps that are the same as the steps (a′) to (d′) except that the epoxy resin layer is replaced with a corresponding epoxy resin layer (e.g., a second epoxy resin layer) and that the first conductive pattern is replaced with a corresponding conductive pattern (e.g., a second conductive pattern) and that the second conductive pattern is replaced with a corresponding conductive pattern (e.g., a third conductive pattern) are repeated.

In the multilayered wiring board manufacturing method of the invention, it is preferable that the second conductive pattern and an optional third conductive pattern are respectively formed on epoxy resin layers each having a smooth surface. In this case, the second and third conductive patterns of a multilayered wiring board produced by the method of the invention are firmly bonded to a smooth substrate, unlike an electroless plating metal layer formed on a surface-roughened resin substrate manufactured by a conventional method. For this, the method of the invention, which enables a high-definition conductive pattern, allows formation of a circuit that has strong adhesion and uniform characteristics without disturbed fine lines due to the roughness of a substrate surface and that exactly corresponds to a design.

In the multilayered wiring board manufacturing method of the invention, it is easy to secure insulating characteristics when a circuit is formed. Specifically, since an electroless copper plating or electroless copper plating catalyst is provided to the entire surface of an insulating substrate in a conventional semi-additive method, the metal remains easily, and, thus, interwire insulating properties of the resultant wiring board reduces easily. In contrast, since an electroless copper plating or an electroless copper plating catalyst is provided to a pattern necessary for wiring rather than the entire surface of an insulating substrate in the manufacturing method of the invention, the electroless copper plating or the catalyst does not remain on the portion other than the pattern which portion is to be insulating. Accordingly, it is possible to form a high-density circuit (wiring) having strong adhesion to a substrate and excellent insulation properties in the wiring board manufacturing method of the invention.

Since it is unnecessary to perform complicated steps such as resist application or etching, and it is possible to form a high-definition pattern without etching, there is no need to treat etching waste water. Namely, the manufacturing method of the invention is preferable from the environmental viewpoint.

According to the conductive pattern forming method, and the conductive film forming method of the invention, a graft polymer is formed by applying energy to the entire surface of an epoxy resin layer obtained by using the epoxy resin composition of the invention or pattern-wise applying to the surface of the epoxy resin layer to generate active points. When the graft polymer is formed, the photopolymerization initiator contained in the epoxy resin layer functions as a polymerization initiator. Accordingly, the graft polymer layer or the graft polymer pattern formed on the epoxy resin layer is chemically and firmly bonded to an insulating substrate via the epoxy resin layer. As a result, the adhesion strength of each of the conductive film and the conductive pattern is practically sufficient even if the insulating substrate has high smoothness.

### EXAMPLES

Hereinafter, the invention sill be specifically described while Examples and Comparative Examples are referred. However, the invention is not limited by Examples and Comparative Examples. The term “part” represents “parts by mass”, unless otherwise specified herein.

### Example 1

First, a first circuit layer (first conductive pattern) was formed on a glass epoxy copper-clad laminate by a subtractive method. Next, the following materials were applied to the first circuit layer with a curtain coater, and the resultant coating was dried at 110° C. for 20 minutes, and cured at 170° C. for 30 minutes to form an epoxy resin layer having a thickness of 45 μm (step (a′)).

Composition of epoxy resin layer

| | | |
|---|---|---|
| (A) | Epoxy resin (EPICOAT 806 manufactured by | 16.7 parts by mass |
| | Japan Epoxy Resins Co., Ltd., and having | |
| | an epoxy equivalence of 167) | |
| (B) | Aminotriazine novolac resin (PHENOLITE | 6.6 parts by mass |
| | LA7052 manufactured by DaiNippon Ink and | |
| | Chemicals. Incorporated, and having a | |
| | nonvolatile content of 62 mass %, and a | |
| | nonvolatile phenolic hydroxyl group | |
| | equivalence of 120) | |
| (C) | Phenoxy resin (FX293 manufactured by Tohto | 30.5 parts by mass |
| | Kasei Co., Ltd., and having a nonvolatile | |
| | content of 40 mass %) | |
| (D) | 2-Ethyl-4-methylimidazole(manufactured by | 0.18 parts by mass |
| | Wako Pure Chemical Industries, Ltd.) | |
| (E) | Cyclohexanone (manufactured by Wako Pure | 23 parts by mass |
| | Chemical Industries, Ltd.) | |
| (F) | Polymerization initiator A (weight-average | 3.5 parts by mass |
| | molecular weight of 46000) | |

The polymerization initiator A is the photopolymerization initiator contained in an epoxy resin composition of the invention, and can be synthesized by a method described in JP-A No. H09-77891.

The content of the polymerization initiator A in the total solid content of the epoxy resin layer was 9.5 mass %.

### Polymerization Initiator A

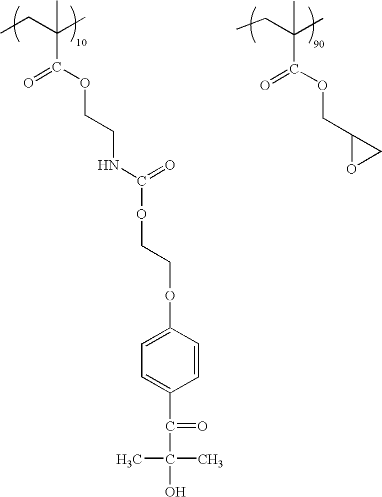

The glass-transition temperature Tg of the formed epoxy resin layer was 175° C., and the coefficient of linear thermal expansion thereof was 40 ppm, and the elongation at beak thereof was 9%. The dielectric dissipation factor of the epoxy resin layer at 1 GHz was 0.025, and the dielectric constant thereof at 1 GHz was 3.0.

The glass-transition temperature Tg was measured by the TMA method. In this method, a specimen was heated at a programming rate of 5° C./minute, and the thermal expansion amount of the specimen in its thickness direction was measured with a thermal analyzer. Then, a graph showing the relationship between temperature and thermal expansion amount was drawn according to the measured values. A tangent was drawn on each of curves that were present respectively before and after a glass-transition temperature, and the point at which these tangents intersect with each other was regarded as the glass-transition temperature of the specimen.

The specimen had a width of 4 mm and a length of 30 mm and was cut from the epoxy resin layer. The measurement was conducted with a device (i.e., TMAQ400 manufactured by TA Instruments) and a load of 0.03 N at a distance between chucks of 15 mm at a programming rate of 5° C./minute within the temperature range of 25° C. to 250° C. The coefficient of linear thermal expansion of the specimen at a temperature equal to or less than the glass-transition temperature was obtained from the measurement results.

The dielectric constant and dielectric dissipation factor of the epoxy resin were measured by a method described in the Abstracts of 18^{th} JIEP Annual Meeting, 2004, p 189, in which device and system for measuring εr and tan δ of an ultra thin sheet manufactured by Keycom Co., Ltd and using a cavity resonator perturbation method was used. The elongation at break of the epoxy resin layer was measure with TENSILON (i.e., RTM-50 manufactured by Orientec, Co., Ltd.) at a crosshead speed of 0.10 mm/min at a distance between chucks of 50 mm at a sample width of 4 mm at room temperature (23° C.) at 50% RH. The measurement was continued until the specimen was broken. The stress and the elongation at a break point were obtained.

Via holes were formed in the epoxy resin layer obtained in the step (a) with a carbon dioxide gas laser (step (c)). Here, the pulse width was 15/12/5 μS, and the number of shots was 1/1/1 (laser processing machine LCO-1B21 manufactured by Hitachi Via Mechanics, Ltd.)

Thereafter, a high molecular weight compound having double bonds was applied to the surface of the epoxy resin layer under the following conditions (step (b)). Application of high molecular weight compound having double bonds

An aqueous solution including, as a compound having double bonds, a hydrophilic polymer (P-1 obtained according to a synthesis described later) which had at least one acrylic group, and at least one carboxyl group, and on or in the side chain(s), at least one polymerizable group was applied to the epoxy resin layer with a rod bar #6, and the resultant coating was dried at 100° C. for 1 minute to form a graft polymer precursor layer having a thickness of 2 μm.

Compound Having Polymerization Group (Application of Graft Precursor Polymer)

<Coating composition liquid 1>

| | |
|---|---|
| Hydrophilic polymer having polymerizable group in | 3.1 g |
| side chain (P-1) | |
| Water | 24.6 g |
| 1-Methoxy-2-propanol | 12.3 g |

### Synthesis of Hydrophilic Polymer (P-1) Having Polymerizable Group in Side Chain

Eighteen grams of polyacrylic acid (average molecular weight of 25,000) was dissolved in 300 g of dimethylacetamide (DMAC), and 0.41 g of hydroquinone, 19.4 g of 2-methacryloyloxyethylisocyanate, and 0.25 g of dibutyltin dilaurate were added to the resultant solution and reaction was carried out at 65° C. for 4 hours. The acid value of the resultant polymer was 7.02 meq/g. Next, the carboxyl groups of the polymer were neutralized with 1 mol/liter (1N) of an aqueous sodium hydroxide solution, and ethyl acetate was added to the reaction system to precipitate the polymer. The polymer was washed well to obtain 18.4 g of a hydrophilic polymer (P-1) having polymerizable groups in or on the side chains.

### Graft Polymer Formation Due to Exposure

A mask with a pattern corresponding to a circuit pattern was brought into close contact with the substrate, and energy was applied to the surface of the polymer (P-1) layer through the mask under the following conditions to obtain a half-finished product in which a graft polymer pattern was directly bonded to the epoxy resin layer.

Applying the energy was performed by irradiating the surface with light emitted by a 1500 W high-pressure mercury lamp (UVX-02516S1LP01 manufactured by Ushio Inc.), and having a wavelength of 254 nm at a light intensity of 38 mW/cm² in an argon atmosphere for 5 minutes. After irradiating the light, the substrate was washed well with deionized water. Thereafter, the substrate was immersed in a 5 wt % sodium bicarbonate solution for 5 minutes and then washed with water.

### Electroless Plating

The substrate was immersed in a 1 mass % aqueous silver nitrate solution (manufactured by Wako Pure Chemical Industries, Ltd.) for 1 minute, and washed with distilled water. The substrate was then subjected to electroless plating at 60° C. for 20 minutes in an electroless plating bath having the following composition.

<Composition of electroless plating bath>

| | | |
|---|---|---|
| Distilled water | 180 | ml |
| Copper sulfate pentahydrate | 1.9 | g |
| EDTA•2Na | 5.6 | g |
| NaOH | 1.6 | g |
| PEG1000 | 0.02 | g |
| Formalin | 1.0 | g |

### Electroplating

The substrate was then subjected to electroplating in an electroplating bath having the following composition at a current density of 3 A/dm² for 20 minutes to form an electrolytic copper plating layer having a thickness of 8 μm, and the electrolytic copper plating layer was post-baked at 150° C. for 60 minutes. Thus, a second circuit layer was obtained and a multilayered wiring board was produced.

It was confirmed that the multilayered wiring board had buried vias obtained by filling the via holes with copper in performing the plating and serving as a part of a conductive circuit.

<Composition of electroplating bath>

| | | |
|---|---|---|
| Distilled water | 1300 | ml |
| Copper sulfate pentahydrate | 133 | g |
| Conc. sulfuric acid | 340 | g |
| Hydrochloric acid | 0.25 | ml |
| Copper Gleam PCM (manufactured by Meltex Inc.) | 9 | ml |

### Example 2

A multilayered wiring board was manufactured in the same manner as in Example 1, except that the following materials were used to form an epoxy resin layer.

Composition of epoxy resin layer

| | | |
|---|---|---|
| (A) | Epoxy resin (NC 3000 manufactured by | 30 parts by mass |
| | Nippon Kayaku Co., Ltd., and having an | |
| | epoxy equivalence of 275) | |
| (B) | Aminotriazine novolac resin (PHENOLITE | 7.1 parts by mass |
| | LA7052 manufactured by DaiNippon Ink | |
| | and Chemicals, Incorporated, and having a | |
| | nonvolatile content of 62 mass %, and a | |
| | nonvolatile phenolic hydroxyl group | |
| | equivalence of 120) | |
| (C) | Phenoxy resin (YP-50EK35 manufactured by | 50 parts by mass |
| | Tohto Kasei Co., Ltd., and having a | |
| | nonvolatile content of 35 mass %) | |
| (D) | 2-Ethyl-4-methylimidazole (manufactured by | 0.29 parts by mass |
| | Wako Pure Chemical Industries, Ltd.) | |
| (E) | Cyclohexanone (manufactured by Wako | 40 parts by mass |
| | Pure Chemical Industries, Ltd.) | |
| (F) | IRGACURE 2959 (manufactured by Ciba | 5.8 parts by mass |
| | Specialty Chemicals K.K.) | |

The content of IRGACURE 2959, which serves as a polymerization initiator, in the total solid content of the epoxy resin layer was 10 mass %.

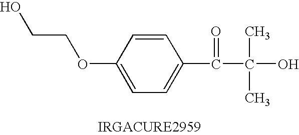

In Example 2, the glass-transition temperature Tg of the epoxy resin layer was 170° C., and the coefficient of linear thermal expansion thereof at 1 GHz was 60 ppm, and the elongation at break thereof was 11%. The dielectric dissipation factor of the epoxy resin layer at 1 GHz was 0.027, and the dielectric constant thereof at 1 GHz was 3.0.

The glass-transition temperature Tg, the coefficient of linear thermal expansion, the elongation at beak, the dielectric dissipation factor and the dielectric constant were measured in the same manner as in Example 1.

### Example 3

A multilayered wiring board was manufactured in the same manner as in Example 1, except that the following materials were used to form an epoxy resin layer.

Composition of epoxy resin layer

| | | |
|---|---|---|
| (A) | Epoxy resin (EPICOAT 807 manufactured by | 16.7 parts by mass |
| | Japan Epoxy Resins Co., Ltd., and having | |
| | an epoxy equivalence of 170) | |
| (B) | Aminotriazine novolac resin (PHENOLITE | 6.6 parts by mass |
| | LA7052 manufactured by DaiNippon Ink and | |
| | Chemicals, Incorporated, and having a | |
| | nonvolatile content of 62 mass %, | |
| | and a nonvolatile phenolic hydroxyl group | |
| | equivalence of 120) | |
| (C) | Phenoxy resin (FX293 manufactured by Tohto | 32 parts by mass |
| | Kasei Co., Ltd., and having a nonvolatile | |
| | content of 40 mass %) | |
| (D) | 2-Ethyl-4-methylimidazole (manufactured by | 0.18 parts by mass |
| | Wako Pure Chemical Industries, Ltd.) | |
| (E) | Methyl ethyl ketone (manufactured by Wako | 60 parts by mass |
| | Pure Chemical Industries, Ltd.) | |
| (F) | Polymerization initiator B (weight-average | 6 parts by mass |
| | molecular weight of 35,000) | |
| (G) | Spherical silica particles (having an average | 25 parts by mass |
| | particle diameter of 1 μm, and treated | |
| | with aminosilane) | |

The polymerization initiator B can be synthesized by a method described in JP-A No. H09-77891. The content of the polymerization initiator B in the total solid content of the epoxy resin layer was 9.3 mass %

### Polymerization Initiator B

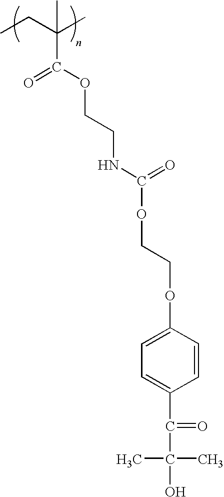

In Example 3, the glass-transition temperature Tg of the epoxy resin layer was 172° C., and the coefficient of linear thermal expansion thereof at 1 GHz was 38 ppm, and the elongation at break thereof was 9%. The dielectric dissipation factor of the epoxy resin layer at 1 GHz was 0.026, and the dielectric constant thereof at 1 GHz was 3.0.

The glass-transition temperature Tg, the coefficient of linear thermal expansion, the elongation at beak, the dielectric dissipation factor and the dielectric constant were measured in the same manner as in Example 1.

### Example 4

A multilayered wiring board was manufactured in the same manner as in Example 1, except that the following materials were used to form an epoxy resin layer.

Composition of epoxy resin layer

| | | |
|---|---|---|
| (A) | Epoxy resin (EPICOAT 806 manufactured by | 16.7 parts by mass |
| | Japan Epoxy Resins Co., Ltd., and | |
| | having an epoxy equivalence of 167) | |
| (B) | Aminotriazine novolac resin (PHENOLITE | 6.6 parts by mass |
| | LA7052 manufactured by DaiNippon Ink | |
| | and Chemicals, Incorporated, and having | |
| | a nonvolatile content of 62 mass %, and a | |
| | nonvolatile phenolic hydroxyl group | |
| | equivalence of 120) | |
| (C) | Phenoxy resin (FX293 manufactured by | 32 parts by mass |
| | Tohto Kasei Co., Ltd., and having a | |
| | nonvolatile content of 40 mass %) | |
| (D) | 2-Ethyl-4-methylimidazole (manufactured by | 0.18 parts by mass |
| | Wako Pure Chemical Industries, Ltd.) | |
| (E) | Cyclohexanone (manufactured by Wako | 60 parts by mass |
| | Pure Chemical Industries, Ltd.) | |
| (F) | Polymerization initiator A (weight-average | 6 parts by mass |
| | molecular weight of 46,000) | |
| (G) | Spherical silica particles (having an average | 25 parts by mass |
| | particle diameter of 1 μm, and treated | |
| | with aminosilane) | |

The content of the polymerization initiator A in the total solid content of the epoxy resin layer was 9.3 mass %.

In Example 4, the glass-transition temperature Tg of the epoxy resin layer was 168° C., and the coefficient of linear thermal expansion thereof at 1 GHz was 37 ppm, and the elongation at break thereof was 9%. The dielectric dissipation factor of the epoxy resin layer at 1 GHz was 0.028, and the dielectric constant thereof at 1 GHz was 3.1.

The glass-transition temperature Tg, the coefficient of linear thermal expansion, the elongation at beak, the dielectric dissipation factor and the dielectric constant were measured in the same manner as in Example 1.

### Example 5

The materials to form an epoxy resin layer used in Example 1 were applied to a polyimide film (KAPTON 500H manufactured by DuPont-Toray Co., Ltd., and having a thickness of 128 μm) with a coating bar, and the resultant coating was cured at 170° C. for 30 minutes to form an epoxy resin layer having a thickness of 8 μm.

In Example 5, the glass-transition temperature Tg of the epoxy resin layer was 173° C., and the coefficient of linear thermal expansion thereof at 1 GHz was 41 ppm, and the elongation at break thereof was 10%. The dielectric dissipation factor of the epoxy resin layer at 1 GHz was 0.026, and the dielectric constant thereof at 1 GHz was 3.1.

The glass-transition temperature Tg, the coefficient of linear thermal expansion, the elongation at beak, the dielectric dissipation factor and the dielectric constant were measured in the same manner as in Example 1.

A high molecular weight compound having double bonds was applied to the surface of the epoxy resin layer in the same manner as in Example 1.

### Graft Polymer Formation Due to Exposure

Energy was applied to the entire surface of the epoxy resin layer under the following conditions to obtain a half-finished product in which a graft polymer was directly bonded to the epoxy resin layer was formed.

Applying the energy was performed by irradiating the entire surface with light emitted by a 1500 W high-pressure mercury lamp (UVX-02516S1LP01 manufactured by Ushio Inc.), and having a wavelength of 254 nm at a light intensity of 38 mW/cm² in an argon atmosphere for 5 minutes. After irradiating the light, the substrate was washed well with deionized water. Thereafter, the substrate was immersed in a 5 wt % sodium bicarbonate solution for 5 minutes and then washed with water.

### Electroless Plating

The substrate was immersed in a 1 mass % aqueous silver nitrate solution (manufactured by Wako Pure Chemical Industries, Ltd.) for 1 minute, and washed with distilled water. The substrate was then subjected to electroless plating at 60° C. for 20 minutes in an electroless plating bath having the same composition as in Example 1.

### Electroplating

The substrate was then subjected to electroplating in an electroplating bath having the same composition as in Example 1 at a current density of 3 A/dm² for 20 minutes to form an electrolytic copper plating layer having a thickness of 8 μm, and the electrolytic copper plating layer was post-baked at 100° C. for 60 minutes. Thus, a conductive film was formed.

### Example 6

A conductive film was manufactured in the same manner as in Example 5, except that the following materials were used to form an epoxy resin layer.

Composition of epoxy resin layer

| | | |
|---|---|---|
| (A) | Polymerization initiator A (epoxy resin having | 2 parts by mass |
| | a weight-average molecular weight of 46,000) | |
| (B) | Bisphenol-F (manufactured by Tokyo | 2.4 parts by mass |
| | Chemical Industry Co. Ltd.) | |
| (C) | Methyl ethyl ketone (manufactured by | 15.6 parts by mass |
| | Wako Pure Chemical Industries, Ltd.) | |
| (D) | 2-Ethyl-4-methylimidazole (manufactured by | 0.02 parts by mass |
| | Wako Pure Chemical Industries, Ltd.) | |

In Example 6, the thickness of the epoxy resin layer was about 3 μm. The glass-transition temperature Tg of the epoxy resin layer was 151° C., and the coefficient of linear thermal expansion thereof at 1 GHz was 77 ppm, and the elongation at break thereof was 6%. The dielectric dissipation factor of the epoxy resin layer at 1 GHz was 0.028, and the dielectric constant thereof at 1 GHz was 3.3.

The glass-transition temperature Tg, the coefficient of linear thermal expansion, the elongation at beak, the dielectric dissipation factor and the dielectric constant were measured in the same manner as in Example 1.

### Example 7

A conductive film was manufactured in the same manner as in Example 5, except that the following materials were used to form an epoxy resin layer.

Composition of epoxy resin layer

| | | |
|---|---|---|
| (A) | Polymerization initiator A (epoxy resin having | 2 parts by mass |
| | a weight-average molecular weight of 46,000) | |
| (B) | 4,4′-Diaminodiphenylsulfone (manufactured | 2.4 parts by mass |
| | by Tokyo Chemical Industry Co., Ltd.) | |
| (C) | Methyl ethyl ketone (manufactured by | 15.6 parts by mass |
| | Wako Pure Chemical Industries, Ltd.) | |
| (D) | 2-Ethyl-4-methylimidazole (manufactured by | 0.02 parts by mass |
| | Wako Pure Chemical Industries, Ltd.) | |

In Example 7, the thickness of the epoxy resin layer was about 3 μm. The glass-transition temperature Tg of the epoxy resin layer was 156° C., and the coefficient of linear thermal expansion thereof at 1 GHz was 70 ppm, and the elongation at break thereof was 7%. The dielectric dissipation factor of the epoxy resin layer at 1 GHz was 0.027, and the dielectric constant thereof at 10 Hz was 3.4. The glass-transition temperature Tg, the coefficient of linear thermal expansion, the elongation at beak, the dielectric dissipation factor and the dielectric constant were measured in the same manner as in Example 1.

### Example 8

The materials to form an epoxy resin layer used in Example 1 were applied to a polyimide film (KAPTON 500H manufactured by DuPont-Toray Co., Ltd., and having a thickness of 128 μm) with a coating bar, and the resultant coating was cured at 170° C. for 30 minutes to form an epoxy resin layer having a thickness of 8 μm. A high molecular weight compound having double bonds was applied to the surface of the epoxy resin layer in the same manner as in Example 1.

### Graft Polymer Formation Due to Exposure

A mask with a pattern corresponding to a circuit pattern was brought into close contact with the substrate, and energy was applied to the epoxy resin layer through the mask under the following conditions to obtain a half-finished product in which a graft polymer pattern was directly bonded to the epoxy resin layer.

Applying the energy was performed by irradiating the surface with light emitted by a 1500 W high-pressure mercury lamp (UVX-02516S1LP01 manufactured by Ushio Inc.), and having a wavelength of 254 nm at a light intensity of 38 mW/cm² in an argon atmosphere for 5 minutes. After irradiating the light, the substrate was washed well with deionized water. Thereafter, the substrate was immersed in a 5 wt % sodium bicarbonate solution for 5 minutes and then washed with water.

### Electroless Plating

The substrate was immersed in a 1 mass % aqueous silver nitrate solution (manufactured by Wako Pure Chemical Industries, Ltd.) for 1 minute, and washed with distilled water. The substrate was then subjected to electroless plating at 60° C. for 120 minutes in an electroless plating bath having the same composition as in Example 1 to form a copper plating layer having a thickness of 8 μm. Then, the resultant plating was post-baked at 100° C. for 60 minutes to form a conductive pattern.

### Comparative Example 1

A multilayered wiring board was manufactured in the same manner as in Example 1, except that a polymerization initiator A was not used.

### Comparative Example 2

A multilayered wiring board was manufactured in the same manner as in Example 2, except that a polymerization initiator (IRGACURE 2959) was not used.

### Comparative Example 3

A conductive film was manufactured in the same manner as in Example 5, except that a polymerization initiator A was not used.

### Comparative Example 4

A conductive pattern was manufactured in the same manner as in Example 8, except that a polymerization initiator A was not used.

The peeling strength and the surface resistance value of the conductive film, the conductive pattern, and the multilayered wiring board obtained in Examples 1 to 8 and Comparative Examples 1 to 4 were measured as follows.

The maximum and minimum peeling strengths of a conductor (conductive pattern) were measured with device TENSILON (RTM-100 manufactured by Orientec Co., Ltd.) on the basis of JIS C 6481, and the average of the maximum and minimum values was used as the peeling strength of the conductor.

The surface resistance value was measured by a four point probe method using a surface resistivity measuring device (LORESTA-EP Model No. MCP-T360 manufactured by Mitsubishi Chemical Corporation) on the basis of JIS K 7194. The measurement results are shown in Table 2.

TABLE 2

| | Peeling | Surface resistance value |
|---|---|---|
| | strength (kN/m) | (Ω/□) |
| Example 1 | 0.8 | 1.9 × 10⁻³ |
| Example 2 | 0.6 | 2.0 × 10⁻³ |
| Example 3 | 0.8 | 1.8 × 10⁻³ |
| Example 4 | 0.9 | 2.1 × 10⁻³ |
| Example 5 | 1.0 | 1.8 × 10⁻³ |
| Example 6 | 0.8 | 1.9 × 10⁻³ |
| Example 7 | 0.8 | 1.9 × 10⁻³ |
| Example 8 | 0.7 | 2.1 × 10⁻³ |
| Comparative Example 1 | 0.2 | 4.5 × 10⁻³ |
| Comparative Example 2 | 0.1 | 5.0 × 10⁻³ |
| Comparative Example 3 | 0.2 | 4.3 × 10⁻³ |
| Comparative Example 4 | 0.1 | 5.1 × 10⁻³ |

As is clear from the results shown in Table 2, it was confirmed that each of the multilayered wiring board, the conductive film and the conductive pattern manufactured in Examples 1 to 8 had higher peeling strength of the conductor or the conductive pattern than the corresponding one of those in Comparative Examples 1 to 4, where a polymerization initiator was not used. It was also confirmed that all the multilayered wiring board of the invention had high reliability of the electrical connection between conductors through buried vias.

1. A thermosetting epoxy resin composition comprising:
an epoxy resin having two or more epoxy groups in one molecule;
a hardener having two or more functional groups in one molecule, the functional groups reacting with the epoxy groups; and
a photopolymerization initiators
wherein the photopolymerization initiator is a high molecular compound.

2. The thermosetting epoxy resin composition of claim 1, wherein the epoxy resin includes a structure having photopolymerization initiation ability as a partial structure.

3. (canceled)

4. The thermosetting epoxy resin composition of claim 1, wherein the hardener is a compound containing a hydroxyl group or an amino group.

5. A conductive film forming method comprising:
(a) forming an epoxy resin layer including the thermosetting epoxy resin composition of claim 1 on an insulating substrate;
(b) forming a graft polymer on a surface of the epoxy resin layer by applying energy to the entire surface of the epoxy resin layer and bonding a polymer having a functional group that interacts with an electroless plating catalyst or a precursor thereof to the entire surface;
(c) providing the electroless plating catalyst or the precursor thereof to the graft polymer; and
(d) forming a conductive film by performing electroless plating.

6. The conductive film forming method of claim 5, wherein the graft polymer is formed on the surface of the epoxy resin layer by bringing a compound having a double bond and a compound having a functional group that interacts with the electroless plating catalyst or the precursor thereof into contact with the epoxy resin layer, applying energy to the entire surface of the epoxy resin layer to generate active points, and polymerizing, using the active points as starting points, the compound having a double bond and the compound having a functional group that interacts with the electroless plating catalyst or the precursor thereof, and is directly bonded to the surface of the epoxy resin layer.

7. The conductive film forming method of claim 5, further comprising performing electroplating after the conductive film is formed.

8. The conductive film forming method of claim 5, wherein the glass-transition temperature Tg of the epoxy resin layer is in the range of 150° C. to 230° C.

9. The conductive film forming method of claim 5, wherein the coefficient of linear thermal expansion of the epoxy resin layer at a temperature equal to or lower than the glass-transition temperature Tg is in the range of 20 ppm to 80 ppm.

10. The conductive film forming method of claim 5, wherein the elongation at break of the epoxy resin layer is in the range of 5% to 15%.

11. The conductive film forming method of claim 5, wherein the dielectric tangent of the epoxy resin layer at 1 GHz is in the range of 0.004 to 0.03.

12. The conductive film forming method of claim 5, wherein the dielectric constant of the epoxy resin layer at 1 GHz is in the range of 2.5 to 3.5.

13. A conductive pattern forming method comprising:
(A) forming an epoxy resin layer including the thermosetting epoxy resin composition of claim 1 on an insulating substrate;
(B) forming a graft polymer on a surface of the epoxy resin layer by pattern-wise applying energy to the surface of the epoxy resin layer and bonding a polymer having a functional group that interacts with an electroless plating catalyst or a precursor thereof to a portion of the epoxy resin layer to which portion energy has been applied;
(C) providing the electroless plating catalyst or the precursor thereof to the graft polymer; and
(D) forming a conductive pattern by performing electroless plating.

14. The conductive pattern forming method of claim 13, wherein the graft polymer is formed on the surface of the epoxy resin layer by bringing a compound having a double bond and a compound having a functional group that interacts with the electroless plating catalyst or the precursor thereof into contact with the epoxy resin layer, pattern-wise applying energy to the surface of the epoxy resin layer to generate active points, and polymerizing, using the active points as starting points, the compound having a double bond and the compound having a functional group that interacts with the electroless plating catalyst or the precursor thereof, and is directly bonded to the surface of the epoxy resin layer.

15. The conductive pattern forming method of claim 13, further comprising performing electroplating after the conductive film is formed.

16. The conductive pattern forming method of claim 13, wherein the glass-transition temperature Tg of the epoxy resin layer is in the range of 150° C. to 230° C.

17. The conductive pattern forming method of claim 13, wherein the coefficient of linear thermal expansion of the epoxy resin layer at a temperature equal to or lower than the glass-transition temperature Tg is in the range of 20 ppm to 80 ppm.

18. The conductive pattern forming method of claim 13, wherein the elongation at break of the epoxy resin layer is in the range of 5% to 15%.

19. The conductive pattern forming method of claim 13, wherein the dielectric tangent of the epoxy resin layer at 1 GHz is in the range of 0.004 to 0.03.

20. The conductive pattern forming method of claim 13, wherein the dielectric constant of the epoxy resin layer at 1 GHz is in the range of 2.5 to 3.5.

21. A multilayered wiring board manufacturing method comprising:
(a′) forming an epoxy resin layer including the thermosetting epoxy resin composition of claim 1 on a first conductive pattern that is formed on an insulating substrate;
(b′) forming a graft polymer pattern on the epoxy resin layer by applying a compound having a double bond and a compound having a functional group that interacts with an electroless plating catalyst or a precursor thereof and pattern-wise irradiating the surface of the epoxy resin layer with ultraviolet light;
(c′) forming a via hole in the epoxy resin layer before or after the graft polymer pattern is formed on the epoxy resin layer; and
(d′) forming a conductive path by subjecting the epoxy resin layer to electroless plating so as to form a second conductive pattern corresponding to the graft polymer pattern and a buried via that electrically connects the first conductive pattern with the second conductive pattern.

22. The multilayered wiring board manufacturing method of claim 21, wherein the graft polymer pattern formed on the epoxy resin layer includes a primary area where the graft polymer exists and a secondary area where the graft polymer does not exist, and the second conductive pattern is a plating film selectively formed on the primary area.

23. The multilayered wiring board manufacturing method of claim 21, wherein the glass-transition temperature Tg of the epoxy resin layer is in the range of 150° C. to 230° C.

24. The multilayered wiring board manufacturing method of claim 21, wherein the coefficient of linear thermal expansion of the epoxy resin layer at a temperature equal to or lower than the glass-transition temperature Tg is in the range of 20 ppm to 80 ppm.

25. The multilayered wiring board manufacturing method of claim 21, wherein the elongation at break of the epoxy resin layer is in the range of 5% to 15%.

26. The multilayered wiring board manufacturing method of claim 21, wherein the dielectric tangent of the epoxy resin layer at 1 GHz is in the range of 0.004 to 0.03.

27. The multilayered wiring board manufacturing method of claim 21, wherein the dielectric constant of the epoxy resin layer at 1 GHz is in the range of 2.5 to 3.5.
